(19) United States
(12) Patent Application Publication
(10) Pub. No.: US 2025/0226801 A1
(43) Pub. Date: Jul. 10, 2025

(54) RF INTEGRATED CIRCUIT FOR PERFORMING CALIBRATION OPERATION FOR STABLE OPERATIONS OF POWER AMPLIFIERS INCLUDED IN PLURALITY OF TRANSMISSION CHANNELS

(71) Applicant: SAMSUNG ELECTRONICS CO., LTD., SUWON-SI (KR)

(72) Inventors: Hongkie Lim, Suwon-si (KR); Doyoon Kim, Suwon-si (KR); Jinhyeok Park, Suwon-si (KR); Jongwon Yun, Suwon-si (KR); Hyunchul Park, Suwon-si (KR); Joonhoi Hur, Suwon-si (KR)

(21) Appl. No.: 18/999,677

(22) Filed: Dec. 23, 2024

(30) Foreign Application Priority Data
Jan. 5, 2024 (KR) 10-2024-0002342
Jun. 26, 2024 (KR) 10-2024-0083585

(51) Int. Cl. H03F 3/24; H03F 1/02; H03F 1/30

(52) U.S. Cl. CPC H03F 3/245; H03F 1/0222; H03F 1/301; H03F 2200/451; H03F 2200/462

(57) ABSTRACT

A radio frequency (RF) integrated circuit includes a plurality of front-end circuits each connected to an antenna and configured to transmit an RF signal, a bias circuit configured to provide biases to power amplifiers of the plurality of front-end circuits, and a bias calibration circuit configured to sense bias currents of the power amplifiers due to the biases and perform a calibration operation on the bias currents based on a sensing result.

### CROSS-REFERENCE TO RELATED APPLICATIONS

This application is based on and claims priority under 35 U.S.C. § 119 to Korean Patent Application Nos. 10-2024-0002342 and 10-2024-0083585, respectively filed on Jan. 5, 2024 and Jun. 26, 2024, in the Korean Intellectual Property Office, the disclosures of which are incorporated by reference herein in their entireties.

### TECHNICAL FIELD

This disclosure relates to generally to a radio frequency (RF) integrated circuit, and more particularly, to an RF integrated circuit configured to calibrate bias currents or bias voltages of power amplifiers to support stable operations of the power amplifiers included in a plurality of transmission channels.

### DISCUSSION OF RELATED ART

In recent wireless communication schemes, phased array and/or beamforming technology has been used to support millimeter wave frequency bands of new radio (NR) networks. For phased array and beamforming technology, RF integrated circuits are designed using high-density and digitally compatible processes (e.g., complementary metal-oxide-semiconductor (CMOS) processes). In this case, constant gain and power characteristics of power amplifiers of the RF integrated circuits are required to improve effective isotropic radiated power (EIRP) of phased array antennas in millimeter wave frequency bands.

To address this requirement, bandgap reference (BGR) circuit/proportional-to-absolute-temperature (PTAT) circuits have been incorporated to ensure that bias currents flowing in or bias voltages provided to the power amplifiers are insensitive to process, voltage, and temperature (PVT) changes. Despite these efforts, as the number of transmission channels of an RF integrated circuit increases, the number of required power amplifiers may increase; actual gains of the power amplifiers may differ from one another due to a variation in current path resistance of each of the power amplifiers, device size local mismatch, etc.; or some of the power amplifiers may not operate properly, which deteriorates the overall performance of the RF integrated circuit.

### SUMMARY

Embodiments of the inventive concept provide an RF integrated circuit that calibrates bias currents or bias voltages of power amplifiers so that the power amplifiers perform stable operations with constant gains.

According to an aspect of the inventive concept, an RF integrated circuit includes a plurality of front-end circuits each connected to an antenna and configured to transmit an RF signal, a bias circuit configured to provide biases to power amplifiers of the plurality of front-end circuits, and a bias calibration circuit configured to sense bias currents of the power amplifiers due to the biases and perform a calibration operation on the bias currents based on a sensing result.

According to another aspect of the inventive concept, an RF integrated circuit includes a first power amplifier configured to amplify a first RF signal based on a first bias, a second power amplifier configured to amplify a second RF signal based on a second bias, a bias circuit configured to provide the first bias to the first power amplifier and provide the second bias to the second power amplifier, a first current sensor configured to sense a first bias current due to the first bias of the first power amplifier and sense a second bias current due to the second bias of the second power amplifier, and a first comparator configured to compare a first sensing result corresponding to the first bias current with a second sensing result corresponding to the second bias current and output a first comparison result, wherein the bias circuit is further configured to adjust the second bias based on the first comparison result.

According to another aspect of the inventive concept, an RF integrated circuit includes a first front-end circuit connected to a first antenna and configured to amplify and transmit a first RF signal, and a bias calibration circuit configured to perform a calibration operation on a first bias voltage of a first power amplifier of the front-end circuit, the first power amplifier including at least first and second stacked amplification stages, wherein the bias calibration circuit includes a first operational amplifier connected to the first stacked amplification stage at a first bias node as part of a feedback loop to maintain the first bias node at the first bias voltage in the calibration operation.

### BRIEF DESCRIPTION OF THE DRAWINGS

Embodiments will be more clearly understood from the following detailed description taken in conjunction with the accompanying drawings in which:

FIGS. 1A and 1B are block diagrams schematically illustrating a wireless communication device, according to an embodiment;

FIG. 2 is a block diagram illustrating a radio frequency (RF) integrated circuit, according to an embodiment;

FIG. 3 is a flowchart for describing a calibration operation on bias currents of power amplifiers of an RF integrated circuit, according to an embodiment;

FIG. 4 is a block diagram for describing a calibration operation of an RF integrated circuit, according to an embodiment;

FIG. 5 is a block diagram for describing a calibration operation of an RF integrated circuit, according to an embodiment;

FIG. 6 is a detailed block diagram illustrating the RF integrated circuit of FIG. 5;

FIG. 7 is a flowchart for describing an operation of calibrating a first bias current of an RF integrated circuit, according to an embodiment;

FIG. 8 is a block diagram for describing a calibration operation of an RF integrated circuit, according to an embodiment;

FIG. 9 is a block diagram for describing a calibration operation of an RF integrated circuit, according to an embodiment;

FIG. 10 is a flowchart for describing a calibration operation according to a mode of an RF integrated circuit, according to an embodiment;

FIG. 11 is a block diagram illustrating an RF integrated circuit, according to an embodiment;

FIGS. 12A and 12B are diagrams for describing an operation of a first current sensor of FIG. 11 according to a selected mode;

FIG. 13 is a table diagram for describing the number of transistors deactivated in a low power mode for each current sensor, according to an embodiment;

FIGS. 14A and 14B are diagrams for describing a method of determining the number of transistors deactivated in a low power mode for each current sensor, according to an embodiment;

FIG. 15 is a flowchart for describing a calibration operation on bias currents of power amplifiers of an RF integrated circuit, according to an embodiment;

FIG. 16 is a block diagram for describing a calibration operation of an RF integrated circuit, according to an embodiment;

FIG. 17 is a flowchart describing a method of determining whether to start a calibration operation of an RF integrated circuit, according to an embodiment;

FIG. 18 is a block diagram for describing a calibration operation of an RF integrated circuit, according to an embodiment;

FIG. 19 is a diagram illustrating an implementation example of a first power amplifier, according to an embodiment;

FIG. 20 is a diagram illustrating an implementation example of a bias circuit of FIG. 19;

FIG. 21 is a diagram illustrating an implementation example of a first power amplifier, according to an embodiment;

FIG. 22 is a circuit diagram illustrating an implementation example of a first power amplifier and a bias circuit, according to an embodiment;

FIG. 23 is a block diagram illustrating a wireless communication device, according to an embodiment; and

FIG. 24 is a conceptual diagram illustrating an Internet of things (IoT) network system to which embodiments are applied.

### DETAILED DESCRIPTION OF EMBODIMENTS

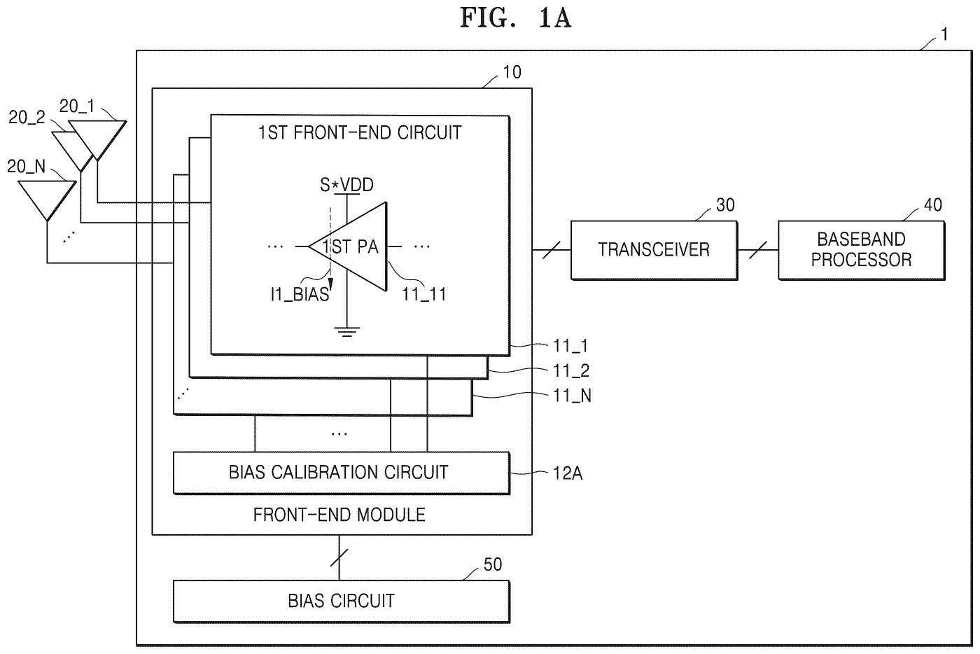

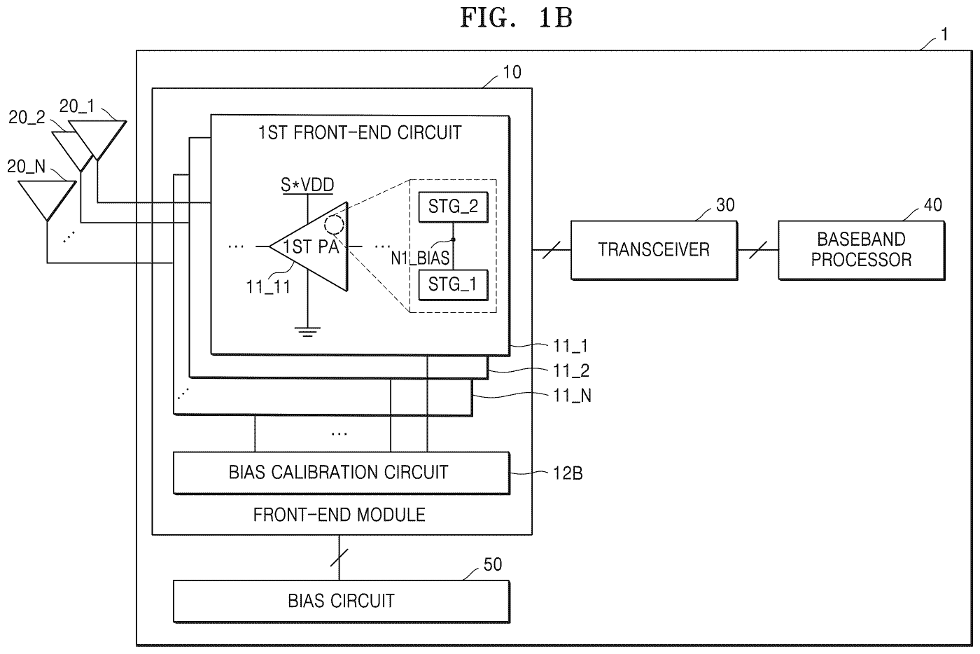

FIGS. 1A and 1B are block diagrams schematically illustrating a wireless communication device 1, according to an embodiment. The wireless communication device 1 may use a communication service based on at least one of a plurality of wireless networks. For example, the wireless communication device 1 may use a communication service based on at least one of a 3^{rd} generation (3G) network, a 4^{th} generation (4G) network, a 5^{th} generation (5G) network, a 6^{th} generation (6G) network, and a wireless local area network (WLAN).

Also, various functions described below may be implemented or supported by artificial intelligence technology or one or more computer programs, each of which includes computer-readable program code and is embodied in a computer-readable medium. The terms “application” and “program” refer to one or more computer programs, software components, sets of instructions, procedures, functions, objects, classes, instances, associated data, or portions thereof suitable for implementation of suitable computer-readable program code. The term “computer-readable program code” includes any type of computer code, including source code, object code, and executable code. The term “computer-readable medium” includes any type of medium capable of being accessed by a computer, such as read-only memory (ROM), random-access memory (RAM), a hard disk drive, a compact disc (CD), a digital video disc (DVD), or any other type of memory. “Non-transitory” computer-readable media exclude wired, wireless, optical, or other communication links that transmit transitory electrical signals or other signals. The non-transitory computer-readable media include media in which data may be permanently stored, and media in which data may be stored and later overwritten, such as a rewritable optical disk or a removable memory device.

In embodiments described below, a hardware approach is described as an example. However, because the embodiments include technology using both hardware and software, the embodiments do not exclude a software-based approach.

Referring to FIG. 1A, the wireless communication device 1 may include a front-end module 10, first to N^{th} (where N is an integer greater than or equal to 2) antennas 20_1 to 20_N, a transceiver 30, a baseband processor 40, and a bias circuit 50. The front-end module 10 may include first to N^{th} front-end circuits 11_1 to 11_N and a bias calibration circuit 12A. The front-end module 10 may be referred to as a radio frequency (RF) front-end module, and the first to N^{th} front-end circuits 11_1 to 11_N may be referred to as RF front-end circuits. The first to N^{th} front-end circuits 11_1 to 11_N may be connected to the first to N^{th} antennas 20_1 to 20_N in a one-to-one manner. In some embodiments, the first to N^{th} antennas 20_1 to 20_N may be included in a phased array antenna and may support a beamforming function. The transceiver 30 may convert a digital signal received from the baseband processor 40 into an analog signal, may perform frequency up-conversion on the analog signal, and transmit a result to the first to N^{th} front-end circuits 11_1 to 11_N. Also, the transceiver 30 may perform frequency down-conversion on an RF signal received from the first to N^{th} front-end circuits 11_1 to 11_N to obtain a digital signal and may transmit the digital signal to the baseband processor 40.

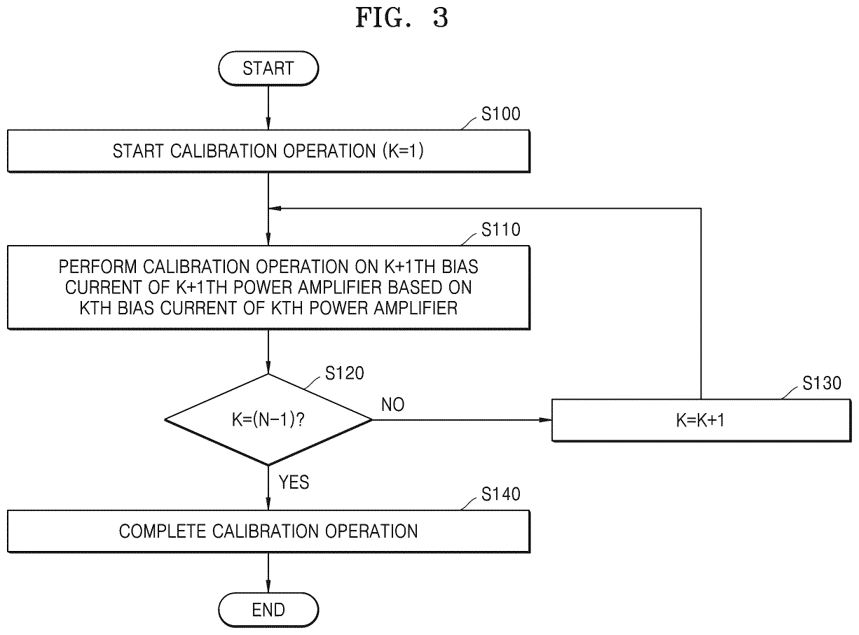

The first to N^{th} front-end circuits 11_1 to 11_N may amplify the RF signal received from the transceiver 30 and may transmit a result to another wireless communication device or a base station through the first to N^{th} antennas 20_1 to 20_N. The first to N^{th} front-end circuits 11_1 to 11_N may include a transmission path (or a transmission chain) and a reception path (or a reception chain). An implementation example of the first to N^{th} front-end circuits 11_1 to 11_N will be described below with reference to FIG. 3.

The first to N^{th} front-end circuits 11_1 to 11_N may include power amplifiers for RF signal amplification. For example, the first front-end circuit 11_1 may include a first power amplifier 11_11.

The first power amplifier 11_11 may be part of a transmission path (or a transmission chain) of the first front-end circuit 11_1, and may amplify a first RF signal input based on a bias (i.e., a bias voltage and/or a bias current) provided from the bias circuit 50 and a supplied first power voltage S*VDD. In this case, in the first power amplifier 11_11, a first bias current I1_BIAS may flow from a node to which the first power voltage S*VDD is applied to ground.

The implementation example of the first front-end circuit 11_1 described above may also be applied to the remaining front-end circuits (i.e., 11_2 to 11_N). In detail, the second to N^{th} front-end circuits 11_2 to 11_N may include second to N^{th} power amplifiers, and second to N^{th} bias currents may flow through the second to N^{th} power amplifiers due to biases provided from the bias circuit 50. In a specific example, a second bias current may flow through a second power amplifier included in the second front-end circuit 11_2, and an N^{th} bias current may flow through an N^{th} power amplifier included in the N^{th} front-end circuit 11_N.

In an embodiment, the bias calibration circuit 12A may sense the first bias current I1_BIAS and the second to N^{th} bias currents, and may perform a calibration operation on the first bias current I1_BIAS and the second to N^{th} bias currents based on sensing results. Calibration may be achieved via feedback control-based adjustments to transistors within the power amplifiers based on the sensing results. For instance, the bias currents of the respective power amplifiers may be calibrated so that the bias currents flowing in all of the power amplifiers are equal (within a tolerance range).

In an embodiment, the bias calibration circuit 12A may sequentially calibrate bias currents of the second to N^{th} power amplifiers based on the order of proximity to the first power amplifier 11_11, based on the first power amplifier 11_11 selected through at least one criterion. For example, the at least one criterion may be the power amplifier located closest to the bias circuit 50 or a power amplifier where a bias current path having the best characteristics (e.g., the most insensitive characteristics to process, voltage, and temperature (PVT) changes) is formed. Hereinafter, a specific embodiment will be described based on an example where the second to N^{th} power amplifiers are implemented adjacent to the first power amplifier 11_11 in that order.

In an embodiment, the bias calibration circuit 12A may sense the first bias current I1_BIAS of the first power amplifier 11_11 and the second bias current of the second power amplifier adjacent to the first power amplifier 11_11, may compare a first sensing result corresponding to the first bias current I1_BIAS and a second sensing result corresponding to the second bias current, and then may calibrate the second bias current based on a comparison result. For example, the bias calibration circuit 12A may calibrate the second bias current so that the second bias current approximates the first bias current I1_BIAS to have a difference less than a threshold value. In some embodiments, the bias calibration circuit 12A may calibrate the second bias current and may also auxiliarily calibrate the first bias current based on a reference bias current applied to the first power amplifier 11_11 as described later.

Next, the bias calibration circuit 12A may sense the calibrated second bias current of the second power amplifier and the third bias current of the third power amplifier adjacent to the second power amplifier, may compare a second sensing result corresponding to the calibrated second bias current with a third sensing result corresponding to the third bias current, and then may calibrate the third bias current based on a comparison result. Thus, successive calibration of adjacent power amplifiers may be performed in a “daisy chain calibration” manner, in which calibration of a next power amplifier in a sequence is referenced to a calibrated current in the previously calibrated (and adjacent) power amplifier. For example, the bias calibration circuit 12A may calibrate the third bias current so that the third bias current approximates the calibrated second bias current or the first bias current I1_BIAS to have a difference less than a threshold value. In some embodiments, the bias calibration circuit 12A may calibrate the third bias current using a current sensor that auxiliarily measures the second bias current after it is calibrated.

In the above manner, the bias calibration circuit 12A may sequentially calibrate the fourth to N^{th} bias currents. As a result of a calibration operation of the bias calibration circuit 12A, the second to N^{th} bias currents may each have a difference less than a threshold value from the first bias current.

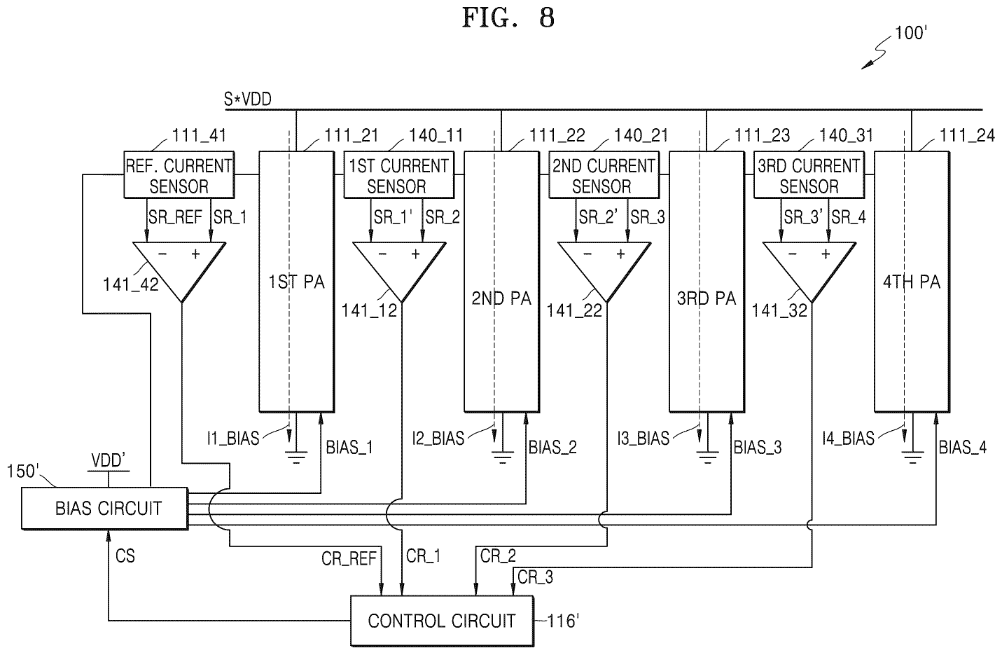

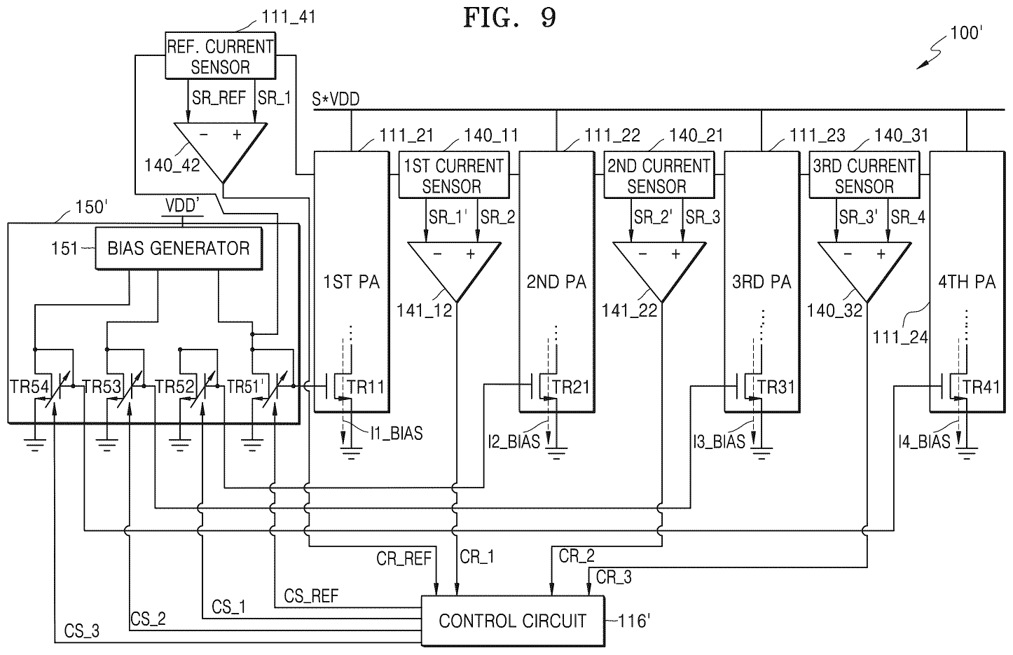

In some embodiments, the bias calibration circuit 12A may calibrate the first bias current I1_BIAS prior to a full-scale calibration operation so that the first bias current I1_BIAS of the first power amplifier 11_11, which serves as a reference current for a calibration operation of the remaining power amplifiers, has an optimal value in an operation of the first power amplifier 11_11. For example, the bias calibration circuit 12A may sense a reference current from the bias circuit 50, and may calibrate the first bias current I1_BIAS based on the reference current (e.g., as in the embodiments of FIGS. 8 and 9).

In an embodiment, the bias calibration circuit 12A may operate according to mode selected from among a general mode and a low power mode in a calibration operation on the first bias current I1_BIAS and the second to N^{th} bias currents. For example, the bias calibration circuit 12A may perform a calibration operation based on a general mode, under a condition not affected by a power state of the wireless communication device 1, for example, in a test stage for mass production of an RF integrated circuit including the front-end module 10, the bias current 50, and the transceiver 30. Also, for example, the bias calibration circuit 12A may perform a calibration operation based on a low power mode, under a condition requiring consideration of a power state of the wireless communication device 1, for example, in a self-calibration stage after shipment of the RF integrated circuit.

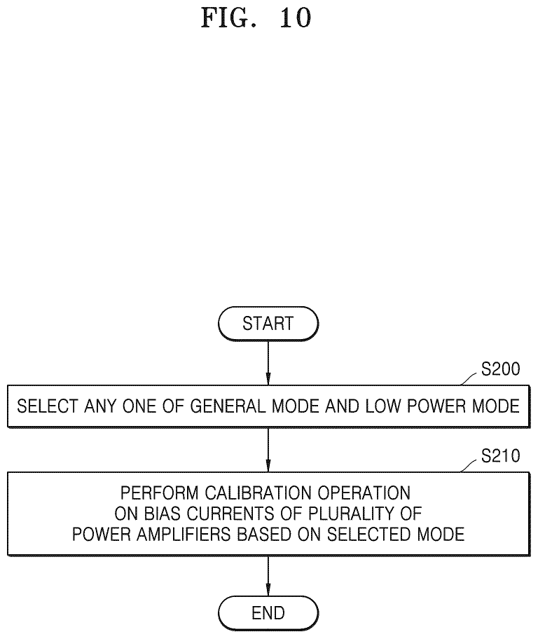

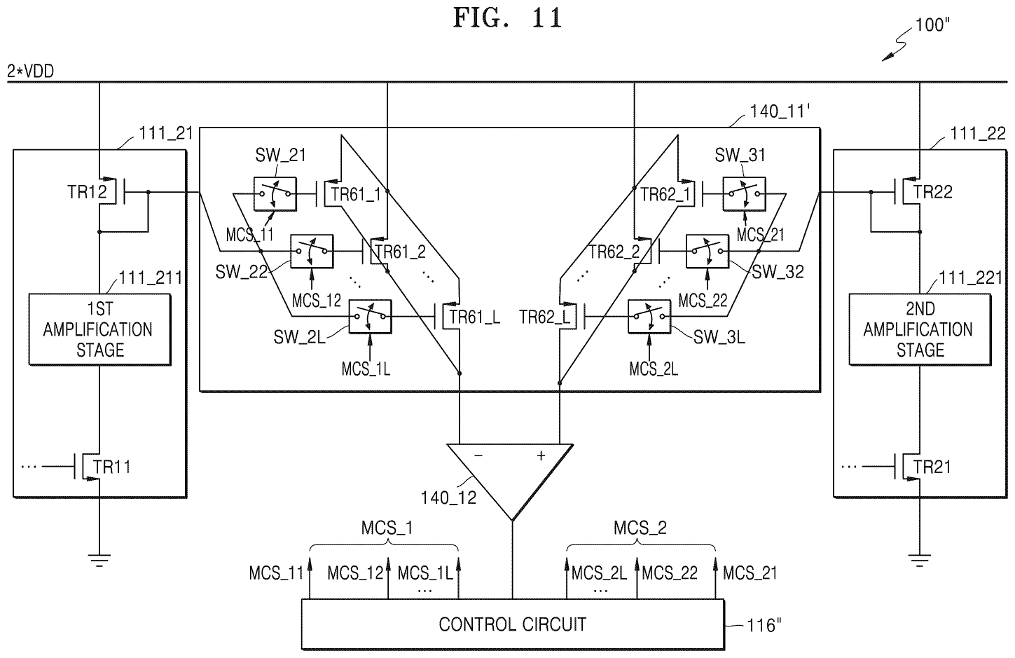

In an embodiment, in a general mode, the bias calibration circuit 12A may perform a calibration operation by activating all elements for sensing the first bias current I1_BIAS and the second to N^{th} bias currents. Also, in an embodiment, in a low power mode, the bias calibration circuit 12A may perform a calibration operation by activating only some of the elements for sensing the bias current I1_BIAS and the second to N^{th} bias currents. As a result, an identifiable difference between bias currents supported by the bias calibration circuit 12A in a general mode may be finer than an identifiable difference between bias currents supported in a low power mode, a specific embodiment of which will be described below with reference to FIGS. 10 and 11.

Herein, an “operation of the bias calibration circuit 12A” may also be considered an operation of the wireless communication device 1 or an operation of the RF integrated circuit.

The bias calibration circuit 12A according to an embodiment may support stable operations of the first power amplifier 11_11 and the second to N^{th} power amplifiers by “uniformly calibrating” (i.e., equalizing) the first bias current I1_BIAS of the first power amplifier 11_11 and the second to N^{th} bias currents of the second to N^{th} power amplifiers of the first to N^{th} front-end circuits 11_1 to 11_N.

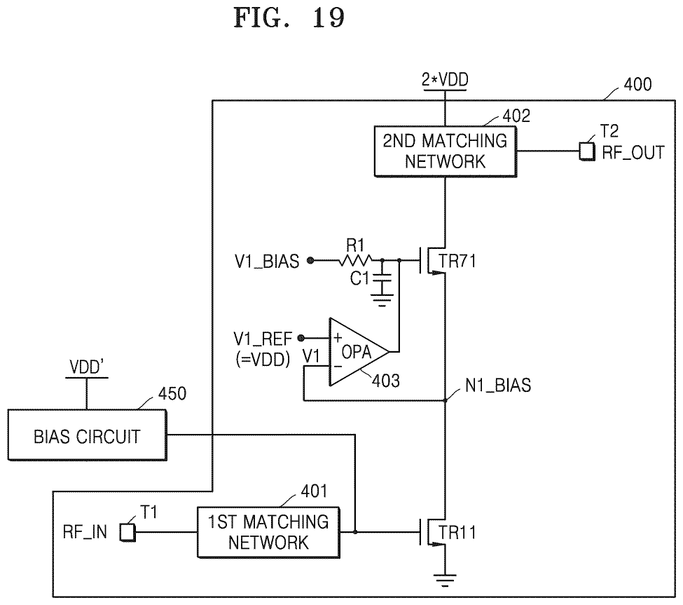

Referring further to FIG. 1B, the first power amplifier 11_11 may include a first amplification stage STG_1 and a second amplification stage STG_2 “stacked” on each other. Here, “stacked” does not require a vertical stacking of stages in a multi-layer integrated circuit. Thus, the stacked stages may be disposed in a same circuit layer or in different circuit layer. For example, the second amplification stage STG_2 may be stacked on the first amplification stage STG_1, and through this structure, a signal amplified by the first amplification stage STG_1 may be additionally amplified by the second amplification stage STG_2. For instance, in an example described below (see FIGS. 19-22), the first power amplifier 11_11 has a cascode configuration in which an output stage is “stacked on” an input stage. The first amplification stage STG_1 and the second amplification stage STG_2 may be connected to each other through a first bias node N1_BIAS.

In an embodiment, a bias calibration circuit 12B may include a first operational amplifier (“op-amp”) (e.g., 403 in FIG. 19, not shown in FIG. 1B) connected to the first power amplifier 11_11 so that a voltage of the first bias node N1_BIAS is maintained at a first target level and configured to perform a calibration operation, in which the voltage is calibrated, by forming a certain feedback loop. (The feedback loop including the op-amp may serve to stabilize the voltage to the target level so that the first stage STG_1 performs as a stable amplifier stage.) Herein, a voltage of a bias node may be referred to as a bias voltage.

In an embodiment, the bias calibration circuit 12B may further include second operational amplifiers (e.g., 403 in FIG. 19, configured as in the first power amplifier, in the same way within the remaining power amplifiers) connected to the second to N^{th} power amplifiers of the second to N^{th} front-end circuits 11_2 to 11_N so that voltages of second to N^{th} bias nodes of the second to N^{th} power amplifiers of the second to N^{th} front-end circuits 11_2 to 11_N are maintained at the first target level and configured to perform a calibration operation by forming certain feedback loops.

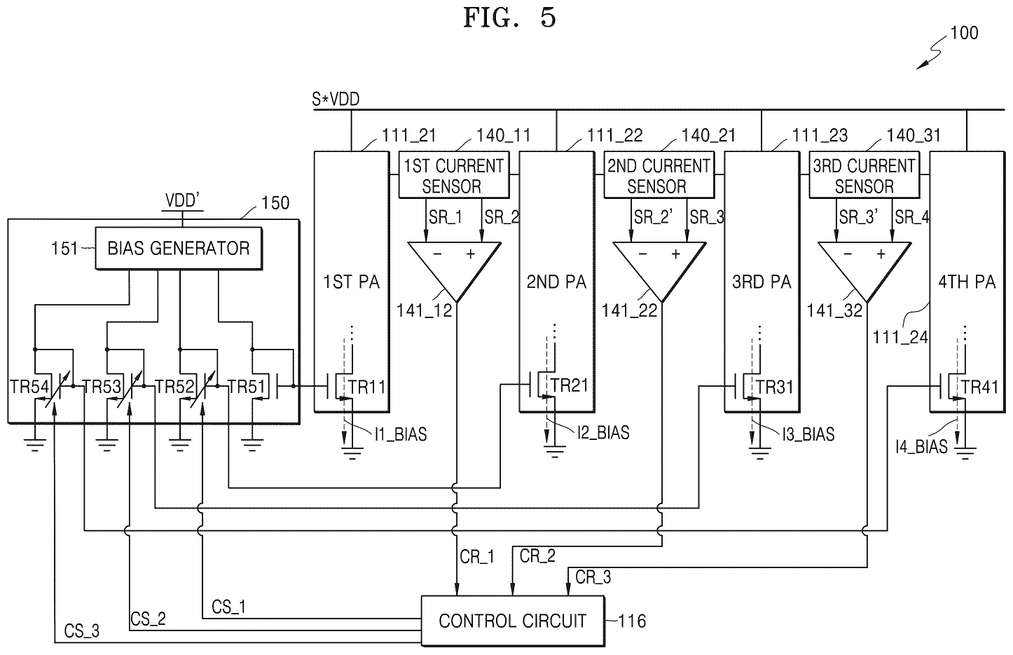

The bias circuit 50 may include a bias generator and a first diode-connected transistor (e.g., TR51 to TR54 in FIG. 5) for providing a first bias to the first power amplifier 11_11 of the first front-end circuit 11_1. (As is known in the art, a diode-connected transistor, such as any of those described herein, may function as a resistance.)

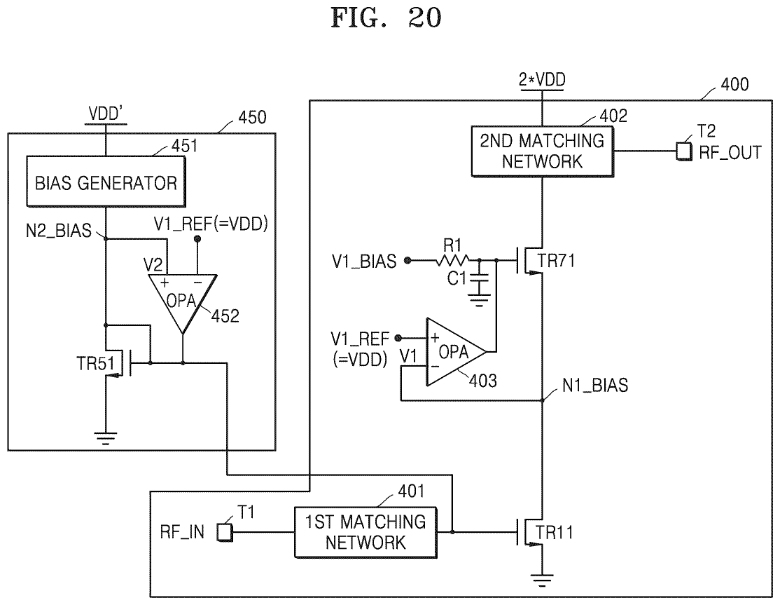

In an embodiment, the bias calibration circuit 12B may further include a third operational amplifier (e.g., 452 in FIG. 20) operating so that a voltage of a node for connecting the first diode-connected transistor to the bias generator is maintained at a second target level (e.g., a level at a gate of an input stage transistor TR11 in a cascode configuration).

Also, the bias circuit 50 may further include diode-connected transistors for providing second to N^{th} biases to the second to N^{th} power amplifiers of the second to N^{th} front-end circuits 11_2 to 11_N.

In an embodiment, the bias calibration circuit 12B may further include fourth operational amplifiers (e.g., 452 in FIG. 20) operating so that voltages of nodes for connecting the second diode-connected transistors to the bias generator are maintained at the second target level.

The bias calibration circuit 12B according to an embodiment may support stable operations of the first power amplifier 11_11 and the second to N^{th} power amplifiers by calibrating a first bias voltage of the first power amplifier 11_11 and second to N^{th} bias voltages of the second to N^{th} power amplifiers of the first to N^{th} front-end circuits 11_1 to 11_N to approximate the first target level.

Also, the bias calibration circuit 12B according to an embodiment may support a stable biasing operation of the bias circuit 50 by calibrating voltages of nodes for providing first to N^{th} biases to the first to N^{th} front-end circuits 11_1 to 11_N of the bias circuit 50 to approximate the second target level.

Herein, an operation of the bias calibration circuit 12B may also be considered an operation of the wireless communication device 1 or an operation of the RF integrated circuit.

Although the bias calibration circuits 12A and 12B are included in the front-end module 10 in FIGS. 1A and 1B, this is only an example, the inventive concept is not limited thereto, and the bias calibration circuits 12A and 12B may not be included in the front-end module 10 or may be included in the bias circuit 50 in other examples. In some embodiments, the bias calibration circuit 12B may be divided into a plurality of parts and the parts may be respectively included in the first to N^{th} front-end circuits 11_1 to 11_N.

Also, herein, the RF integrated circuit may include an antenna module including the first to N^{th} antennas 20_1 to 20_N, the front-end module 10, the transceiver 30, and the bias circuit 50. Alternatively, the antennas 20_1 to 20_N are not included within the RF integrated circuit but are instead included in other structures that are mechanically and electrically connected to the RF integrated circuit. The RF integrated circuit may be implemented as a single chip or may be implemented to include a plurality of chips.

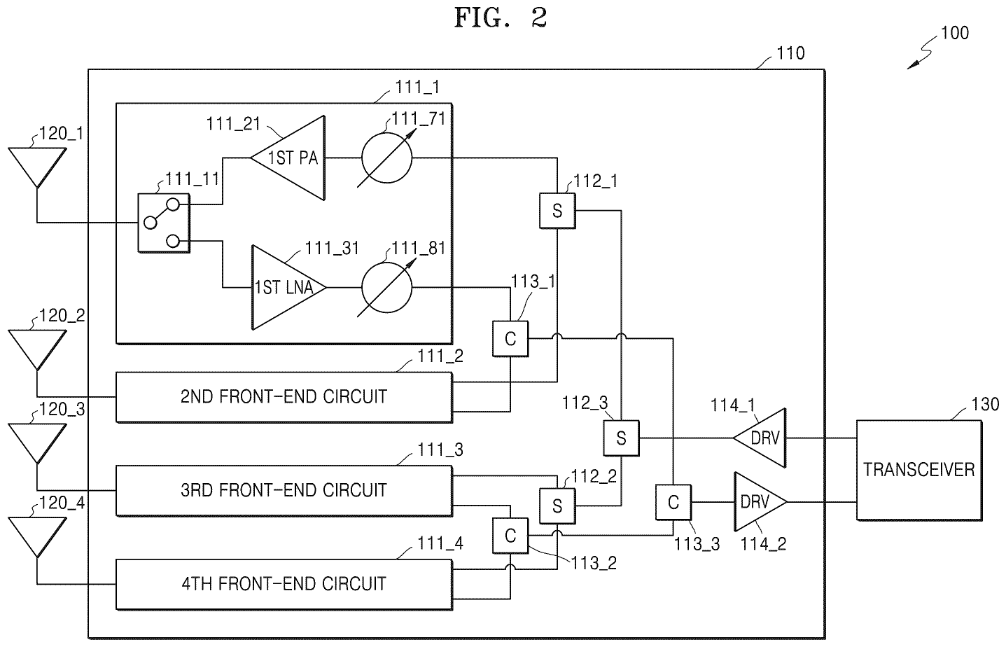

FIG. 2 is a block diagram illustrating an RF integrated circuit 100, according to an embodiment. Although the RF integrated circuit 100 includes four front-end circuits in FIG. 2, this is only an example for effectively describing the inventive concept, and thus, the inventive concept may be applied to the RF integrated circuit 100 including a larger number of front-end circuits. In FIG. 2, biasing circuitry and biasing calibration circuitry are omitted for clarity of illustration, but these may be included within the RF integrated circuit 100.

Referring to FIG. 2, the RF integrated circuit 100 may include a front-end module 110, first to N^{th} antennas 120_1 to 120_4, and a transceiver 130. The front-end module 110 may include first to fourth front-end circuits 111_1 to 111_4, first to third splitters 112_1 to 112_3, first to third combiners 113_1 to 113_3, a first driver 114_1, and a second driver 114_2.

The first front-end circuit 111_1 may include a first switch element 111_11, a first power amplifier 111_21, a first low noise amplifier 111_31, and first phase shifters 111_71 and 111_81. The first power amplifier 111_21 and the first phase shifter 111_71 may constitute a first transmission path, and the first low noise amplifier 111_31 and the first phase shifter 111_81 may constitute a first reception path. Any one of the first transmission path and the first reception path may be selectively connected to the first antenna 120_1.

An implementation example of the first front-end circuit 111_1 may also be applied to the second to fourth front-end circuits 111_2 to 111_4. The second front-end circuit 111_2 may include a second transmission path and a second reception path, and any one of the second transmission path and the second reception path may be selectively connected to the second antenna 120_2. The third front-end circuit 111_3 may include a third transmission path and a third reception path, and any one of the third transmission path and the third reception path may be selectively connected to the third antenna 120_3. Also, the fourth front-end circuit 111_4 may include a fourth transmission path and a fourth reception path, and any one of the fourth transmission path and the fourth reception path may be selectively connected to the fourth antenna 120_4.

The first transmission path of the first end circuit 111_1 and the second transmission path of the second front-end circuit 111_2 may be connected to the first splitter 112_1, and the third transmission path of the third front-end circuit 111_3 and the fourth transmission path of the fourth front-end circuit 111_4 may be connected to the second splitter 112_2. The first splitter 112_1 and the second splitter 112_2 may be connected to the third splitter 112_3. The third splitter 112_3 may separate an RF signal output from the first driver 114_1 and may provide the RF signal to the first splitter 112_1 and the second splitter 112_2. The first splitter 112_1 may separate the separated RF signal once more, and may provide a first RF signal to the first transmission path of the first front-end circuit 111_1 and may provide a second RF signal to the second transmission path of the second front-end circuit 111_2. Also, the second splitter 112_2 may separate the separated RF signal once more, and may provide a third RF signal to the third transmission path of the third front-end circuit 111_3 and may provide a fourth RF signal to the fourth transmission path of the fourth front-end circuit 111_4.

The first reception path of the first front-end circuit 111_1 and the second reception path of the second front-end circuit 111_2 may be connected to the first combiner 113_1, and the third reception path of the third front-end circuit 111_3 and the fourth reception path of the fourth front-end circuit 111_4 may be connected to the second combiner 113_2. The first combiner 113_1 and the second combiner 113_2 may be connected to the third combiner 113_3. The first combiner 113_1 may combine the first RF signal with the second RF signal received from the first reception path of the first front-end circuit 111_1 and the second reception path of the second front-end circuit 111_2 and may provide a result to the third combiner 113_3. The second combiner 113_2 may combine the third RF signal with the fourth RF signal received from the third reception path of the third front-end circuit 111_3 and the fourth reception path of the fourth front-end circuit 111_4 and may provide a result to the third combiner 113_3. The third combiner 113_3 may combine the RF signals received from the first and second combiners 113_1 and 113_2 and may output a result to the second driver 114_2.

The RF integrated circuit 100 according to an embodiment may perform a calibration operation on bias currents or bias voltages of power amplifiers including the first power amplifier 111_21 of the first front-end circuit 111_1 and the second to fourth power amplifiers of the second to fourth front-end circuits 111_2 to 111_4.

According to the inventive concept, amplifier to amplifier bias current/bias voltage calibration according to the techniques taught herein may also be applied to various other amplifiers (e.g., low noise amplifiers including the first low noise amplifier 111_31) in the RF integrated circuit 100.

FIG. 3 is a flowchart for describing a calibration operation on bias currents of power amplifiers of an RF integrated circuit, according to an embodiment.

Referring to FIG. 3, in operation S100, an RF integrated circuit may start a calibration operation. For example, the RF integrated circuit may start a calibration operation by initializing a variable ‘K’ to ‘1’.

In operation S110, the RF integrated circuit may perform a calibration operation on a K+1^{th} bias current of a K+1^{th} power amplifier based on a K^{th} bias current of a K^{th} power amplifier. For example, the RF integrated circuit may sense the K^{th} bias current and the K+1^{th} bias current, may compare a sensing result of the K^{th} bias current with a sensing result of the K+1^{th} bias current, and may calibrate the K+1^{th} bias current based on a result of the comparison.

In operation S120, the RF integrated circuit may determine whether ‘K’ has reached ‘(N−1)’. ‘N’ may have a value corresponding to the total number of power amplifiers included in the RF integrated circuit and to be calibrated based on a measured bias current of another power amplifier. (Note that the first power amplifier may also be calibrated based on a reference current, as described later.)

When operation S120 is ‘NO’, in operation S130, the RF integrated circuit may increment ‘K’ and then may perform operation S110 again.

When operation S120 is ‘YES’, in operation S140, the RF integrated circuit may complete the calibration operation on bias currents of power amplifiers.

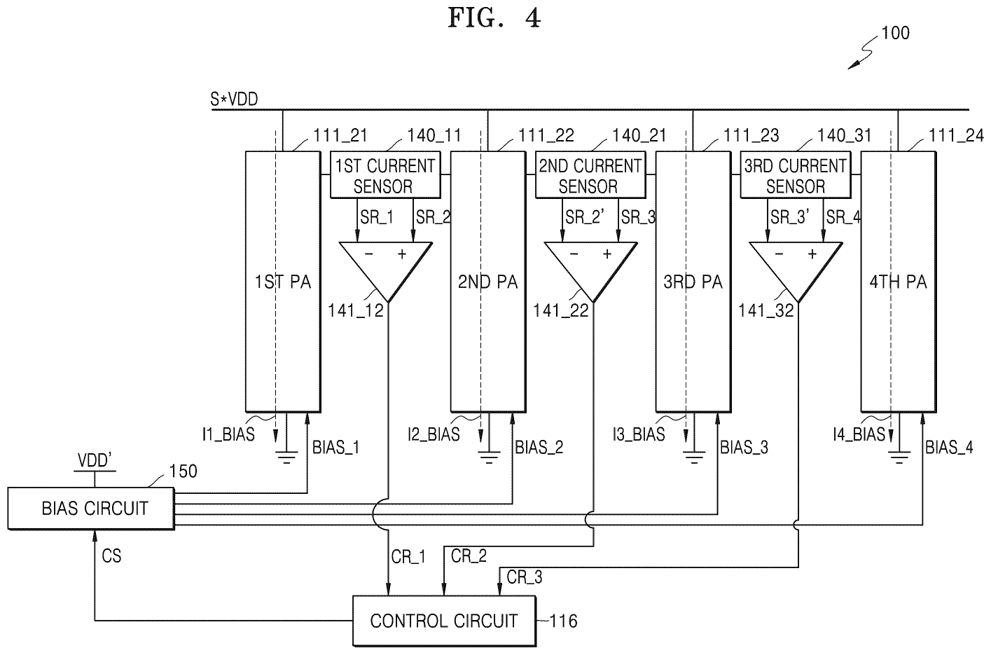

FIG. 4 is a block diagram for describing a calibration operation of the RF integrated circuit 100, according to an embodiment.

Referring to FIG. 4, the RF integrated circuit 100 may include first to fourth power amplifiers 111_21 to 111_24, first to third current sensors 140_11, 140_21 and 140_31, first to third comparators 141_12, 141_22 and 141_32, a control circuit 116, and a bias circuit 150 (an example of the bias circuit 50). The bias calibration circuit 12A of FIG. 1A (or the bias calibration circuit 12B of FIG. 1B) may include the first to third current sensors 140_11 to 140_31, the first to third comparators 141_12 to 141_32, and the control circuit 116.

A first power voltage S*VDD may be supplied to the first to fourth power amplifiers 111_21 to 111_24. ‘S’ may be determined according to the number of stacked amplification stages of the first to fourth power amplifiers 111_21 to 111_24. For example, when the number of stacked amplification stages is 2, ‘S’ may correspond to ‘2’. A second power voltage VDD′ may be provided to the bias circuit 150, and may have the same or different voltage as VDD.

The bias circuit 150 may generate a first bias BIAS_1 and may provide the first bias BIAS_1 to the first power amplifier 111_21. (Some examples describing ways to provide a stable first bias BIAS_1 at a target level are described later.) The bias circuit 150 may generate a second bias BIAS_2 and may provide the second bias BIAS_2 to the second power amplifier 111_22, may generate a third bias BIAS_3 and may provide the third bias BIAS_3 to the third power amplifier 111_23, and may generate a fourth bias BIAS_4 and may provide the fourth bias BIAS_4 to the fourth power amplifier 111_24.

The first power amplifier 111_21 may perform an amplification operation based on the first bias BIAS_1 and the first power voltage S*VDD, and in this case, a first bias current I1_BIAS may flow through the first power amplifier 111_21. The second power amplifier 111_22 may perform an amplification operation based on the second bias BIAS_2 and the first power voltage S*VDD, and in this case, a second bias current I2_BIAS may flow through the second power amplifier 111_22. The third power amplifier 111_23 may perform an amplification operation based on the third bias BIAS_3 and the first power voltage S*VDD, and in this case, a third bias current I3_BIAS may flow through the third power amplifier 111_23. The fourth power amplifier 111_24 may perform an amplification operation based on the fourth bias BIAS_4 and the first power voltage S*VDD, and in this case, a fourth bias current I4_BIAS may flow through the fourth power amplifier 111_24.

Hereinafter, a calibration operation on the second bias current I2_BIAS will be described.

In an embodiment, the first current sensor 140_11 and the first comparator 141_12 may be located between the first power amplifier 111_21 and the second power amplifier 111_22. The first current sensor 140_11 may sense the first bias current I1_BIAS of the first power amplifier 111_21 and output a first sensing result SR_1, and may sense the second bias current I2_BIAS of the second power amplifier 111_22 and may output a second sensing result SR_2.

In an embodiment, the first comparator 141_12 may receive the first sensing result SR_1 through a negative input terminal and may receive the second sensing result SR_2 through a positive input terminal, or vice versa. The first comparator 141_12 may output a first comparison result CR_1 based on a difference between the first sensing result SR_1 and the second sensing result SR_2. In a specific example, the first comparator 141_12 may output the first comparison result CR_1 including a plurality of bits indicating how much the second sensing result SR_2 differs from the first sensing result SR_1. The control circuit 116 may generate a control signal CS based on the first comparison result CR_1 and may provide the control signal CS to the bias circuit 150. The bias circuit 150 may adjust the second bias BIAS_2 based on the control signal CS.

In an embodiment, the control circuit 116 may perform the above operation by using the first current sensor 140_11 and the first comparator 141_12 at least once to control the second bias current I2_BIAS to approximate the first bias current I1_BIAS to have a difference less than a threshold value.

Hereinafter, a calibration operation on the third bias current I3_BIAS will be described.

In an embodiment, the second current sensor 140_21 and the second comparator 141_22 may be located between the second power amplifier 111_22 and the third power amplifier 111_23. The second current sensor 140_21 may sense the calibrated second bias current I2_BIAS of the second power amplifier 111_22 and may output an auxiliary second sensing result SR_2′, and may sense the third bias current I3_BIAS of the third power amplifier 111_23 and may output a third sensing result SR_3.

In an embodiment, the second comparator 141_22 may receive the auxiliary second sensing result SR_2′ through a negative input terminal and may receive the third sensing result SR_3 through a positive input terminal, or vice versa. The second comparator 141_22 may output a second comparison result CR_2 based on a difference between the auxiliary second sensing result SR_2′ and the third sensing result SR_3. In a specific example, the second comparator 141_22 may output the second comparison result CR_2 including a plurality of bits indicating how much the third sensing result SR_3 differs from the auxiliary second sensing result SR_2′. The control circuit 116 may generate a control signal CS based on the second comparison result CR_2 and may provide the control signal CS to the bias circuit 150. The bias circuit 150 may adjust the third bias BIAS_3 based on the control signal CS.

In an embodiment, the control circuit 116 may perform the above operation by using the second current sensor 140_21 and the second comparator 141_22 at least once to control the third bias current I3_BIAS to approximate the calibrated second bias current I2_BIAS to have a difference less than a threshold value.

Hereinafter, a calibration operation on the fourth bias current I4_BIAS will be described.

In an embodiment, the third current sensor 140_31 and the third comparator 141_32 may be located between the third power amplifier 111_23 and the fourth power amplifier 111_24. The third current sensor 140_31 may sense the calibrated third bias current I3_BIAS of the third power amplifier 111_23 and may output a third' sensing result SR_3′, and may sense the fourth bias current I4_BIAS of the fourth power amplifier 111_24 and may output a fourth sensing result SR_4.

In an embodiment, the third comparator 141_32 may receive the third′ sensing result R_3′ through a negative input terminal and may receive the fourth sensing result SR_4 through a positive input terminal. The third comparator 141_32 may output a third comparison result CR_3 based on the third′ sensing result SR_3′ and the fourth sensing result SR_4. In a specific example, the third comparator 141_32 may output the third comparison result CR_3 including a plurality of bits indicating how much the fourth sensing result SR_4 differs from the third′ sensing result SR_3′. The control circuit 116 may generate a control signal CS based on the third comparison result CR_3 and may provide the control signal CS to the bias circuit 150. The bias circuit 150 may adjust the fourth bias BIAS_4 based on the control signal CS.

In an embodiment, the control circuit 116 may perform the above operation by using the third current sensor 140_31 and the third comparator 141_32 at least once to control the fourth bias current I4_BIAS to approximate the calibrated third bias current I3_BIAS to have a difference less than a threshold value.

As described above, based on the order of proximity to the first power amplifier 111_21, the second bias current I2_BIAS of the second power amplifier 111_22, the third bias current I3_BIAS of the third power amplifier 111_23, and the fourth bias current I4_BIAS of the fourth power amplifier 111_24 may be sequentially calibrated. In this case, the first power amplifier 111_21 may be located closest to the bias circuit 150.

In an embodiment, the control circuit 116 may select any one of a general mode and a low power mode and may perform a calibration operation based on the selected mode. For example, the control circuit 116 may control the first to third current sensors 140_11 to 140_31 so that power consumption of the first to third current sensors 140_11 to 140_31 in a low power mode is less than that in a general mode.

In some embodiments, the control circuit 116 may select any one of a first amplification mode and a second amplification mode and may perform a calibration operation based on the selected mode. For example, in the first amplification mode, the control circuit 116 may control the first to third current sensors 140_11 to 140_31 to sense the first to fourth bias currents I1_BIAS to I4_BIAS and output sensing results corresponding to certain multiples of the first to fourth bias currents I1_BIAS to I4_BIAS. For example, in the second amplification mode, the control circuit 116 may control the first to third current sensors 140_11 to 140_31 to sense the first to fourth bias currents I1_BIAS to I4_BIAS and output sensing results corresponding to less than 1 times (i.e., a fraction of) the first to fourth bias currents I1_BIAS to I4_BIAS. Here, the first amplification mode may correspond to an implementation example of a general mode, and the second amplification mode may correspond to an implementation example of a low power mode.

Modes will be described below in detail.

FIG. 5 is a block diagram for describing a calibration operation of the RF integrated circuit 100, according to an embodiment. For convenience of explanation, in the description of FIG. 5, the same description as that made with reference to FIG. 4 will be omitted.

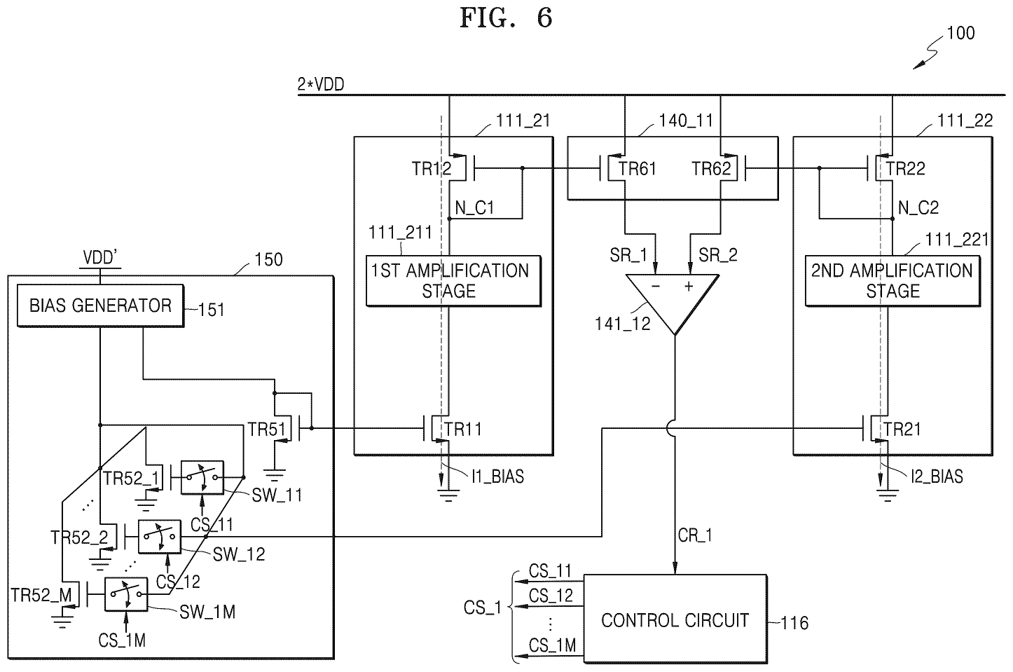

Referring to FIG. 5, the bias circuit 150 may include a bias generator 151 and transistors TR51, TR52, TR53 and TR54. In an embodiment, transistors TR51 to TR54 may be diode-connected transistors, and the transistors TR52 to TR54 may be both variable transistors and diode-connected. Herein, a variable transistor may include a circuit for adjusting a width (or a length) of a channel. A specific implementation example will be described with reference to FIG. 6.

The first power amplifier 111_21 may include a transistor TR11, the second power amplifier 111_22 may include a transistor TR21, the third power amplifier 111_23 may include a transistor TR31, and the fourth power amplifier 111_24 may include a transistor TR41.

The bias generator 151 may include at least one of a BGR circuit and a PTAT circuit, and may output a reference current to each of the transistors TR51 to TR54.

The first power amplifier 111_21 may receive a first bias through a current mirror including the transistors TR11 and TR51. In detail, the reference current output from the bias generator 151 may be copied at a ratio determined by the characteristics of transistors TR51 and TR11 so that the first bias current I1_BIAS flows through the first power amplifier 111_21. For example, a ratio for copying the reference current may be determined based on a ratio between a width and a length of a channel of the transistor TR11 and a ratio between a width and a length of a channel of the transistor TR51. For example, the first bias may be provided to a gate terminal (“gate”) of the transistor TR11 through a drain-gate connection of the transistor TR51 as illustrated.

The second power amplifier 111_22 may receive a second bias through a current mirror including the transistors TR21 and TR52. In detail, the reference current output from the bias generator 151 may be copied at a ratio determined by the characteristics of the transistors TR52 and TR21 so that the second bias current I2_BIAS flows through the second power amplifier 111_22. For example, the second bias may be provided to a gate of the transistor TR21 through a gate of the transistor TR52. Also, the control circuit 116 may generate a first control signal CS_1 for adjusting a width or a length of a channel of the transistor TR52 based on the first comparison result CR_1 and may provide the first control signal CS_1 to the transistor TR52. Such channel width/length adjustment may be accomplished by selectively switching a number of sub-transistors TR52 into/out of the circuit in parallel, as described in relation to FIG. 6. Alternatively, a control signal is applied to a bulk region of a single transistor TR52 to make the width/length adjustment. As a result, in either case, a ratio between the transistors TR52 and r TR21 may change and thus, the second bias current I2_BIAS may be calibrated (e.g., adjusted to equal the first bias current I1_BIAS).

The third power amplifier 111_23 may receive a third bias through a current mirror including the transistors TR31 and TR53. In detail, the reference current output from the bias generator 151 may be copied at a ratio determined by the characteristics of transistors TR53 and TR31 so that the third bias current I3_BIAS flows through the third power amplifier 111_23. For example, the third bias may be provided to a gate terminal of the 31^{st} transistor TR31 through a gate terminal of the transistor TR53. Also, the control circuit 116 may generate a second control signal CS_2 for adjusting a width or a length of a channel of the transistor TR53 based on the second comparison result CR_2 and may provide the second control signal CS_2 to the transistor TR53. As a result, a ratio between the transistors TR53 and TR31 may change, and thus, the third bias current I3_BIAS may be calibrated.

The fourth power amplifier 111_24 may receive a fourth bias through a current mirror including the transistors TR41 and TR54. In detail, the reference current output from the bias generator 151 may be copied at a ratio determined by the characteristics of the transistors TR54 and TR41 so that the fourth bias current I4_BIAS flows through the fourth power amplifier 111_24. For example, the fourth bias may be provided to a gate terminal of the transistor TR41 through a gate terminal of the transistor TR54. Also, the control circuit 116 may generate a third control signal CS_3 for adjusting a width or a length of a channel of the transistor TR54 based on the third comparison result CR_3 and may provide the third control signal CS_3 to the transistor TR54. As a result, a ratio between the transistors TR54 and TR41 may change, and thus, the fourth bias current I4_BIAS may be calibrated.

Herein, transistors schematically illustrated with source terminal arrows pointing away from the gate terminal are n-type metal-oxide-semiconductor (NMOS) transistors, and transistors with source terminal arrows pointing towards the gate terminal are p-type metal-oxide-semiconductor (PMOS) transistors. Although the transistors (e.g., TR11 to TR41 and TR51 to TR54) in FIG. 5 are illustrated as NMOS transistors, this is only an example, the inventive concept is not limited thereto, and the transistors (e.g., TR11 to TR41 and TR51 to TR54) may be PMOS or other types of transistors in other embodiments.

FIG. 6 is a detailed block diagram illustrating an example schematic of the RF integrated circuit 100 of FIG. 5. For convenience of explanation, in the description of FIG. 6, the same description as that made with reference to FIGS. 4 and 5 will be omitted. In FIG. 6, the RF integrated 100 including a configuration for calibrating the second bias current I2_BIAS of the second power amplifier 111_22 is illustrated, and it will be understood that the embodiment described below may be applied to configurations for calibrating other bias currents.

Referring to FIG. 6, the first power amplifier 111_21 may include the transistor TR11, a transistor TR12, and a first amplification stage 111_211. The second power amplifier 111_22 may include the transistor TR21, a transistor TR22, and a second amplification stage 111_221. The first current sensor 140_11 may include a transistor TR61 and a transistor TR62.

In an embodiment, the first current sensor 140_11 may sense the first bias current I1_BIAS through a current mirror including the transistor TR12 and the transistor TR61. In detail, the first bias current I1_BIAS may be copied at a ratio determined by the characteristics of the transistors TR12 and TR61 and a first sensing result may be output. Also, the second bias current I2_BIAS may be copied at a ratio determined by the characteristics of the transistors TR22 and TR62 and a second sensing result may be output. As such, the first current sensor 140_11 may provide a first sensing result corresponding to the first bias current I1_BIAS and a second sensing result corresponding to the second bias current I2_BIAS to the first comparator 141_12.

In an embodiment, in the first power amplifier 111_21, the transistor TR11 operating as an amplification stage and the first amplification stage 111_211 may constitute amplification stages stacked on each other (e.g., in a cascode configuration as in FIG. 19), and in the second power amplifier 111_22, the transistor TR21 operating as an amplification stage and the second amplification stage 111_221 may constitute amplification stages stacked on each other (e.g., in a cascode configuration).

In an embodiment, the first current sensor 140_11 may be connected to a node N_C1 between a node of the first power amplifier 111_21 to which a first power voltage 2*VDD is applied and the first amplification stage 111_211 to sense the first bias current I1_BIAS. Also, the first current sensor 140_11 may be connected to a node N_C2 between a node of the second power amplifier 111_22 to which the first power voltage 2*VDD is applied and the second amplification stage 111_221 to sense the second bias current I2_BIAS. That is, the first current sensor 140_11 may be located closer to the nodes of the first and second power amplifiers 111_21 and 111_22 to which the first power voltage 2*VDD is applied than a ground node of the first and second power amplifiers 111_21 and 111_22. This may be an arrangement considered for stable operations of the first and second power amplifiers 111_21 and 111_22 and an effective calibration operation.

In an embodiment, the control circuit 116 may generate 11^{th} to 1M^{th} control signals CS_11 to CS_1M based on the first comparison result CR_1. The 11^{th} to 1M^{th} control signals CS_11 to CS_1M are signals included in the first control signal CS_1 of FIG. 5 and may be referred to as switching control signals.

In an embodiment, the transistor TR52 may include transistors TR52_1 to TR52_M and switch elements SW_11 to SW_1M (where M is an integer of two or more).

Drain terminals of the transistors TR52_1 to TR52_M may be connected to a node to which a reference current is applied, source terminals of the transistors TR52_1 to TR52_M may be grounded, and gate terminals of the transistors TR52_1 to TR52_M may be connected to the switch elements SW_11 to SW_1M in a one-to-one manner.

Switch elements SW_11 to SW_1M may be turned on/off based on the control signals CS_11 to CS_1M received from the control circuit 116. That is, the control circuit 116 may calibrate the second bias current I2_BIAS by adjusting the number of activated transistors (or the number of transistors connected to the transistor TR21) from among the transistors TR52_1 to TR52_M based on the first comparison result CR_1.

Although some transistors (e.g., TR12, TR61, TR62, and TR22) are shown as PMOS transistors in FIG. 6, this is only an example, the inventive concept is not limited thereto, and some transistors (e.g., TR12, TR61, TR62, and TR22) may alternatively be NMOS transistors or other types of transistors.

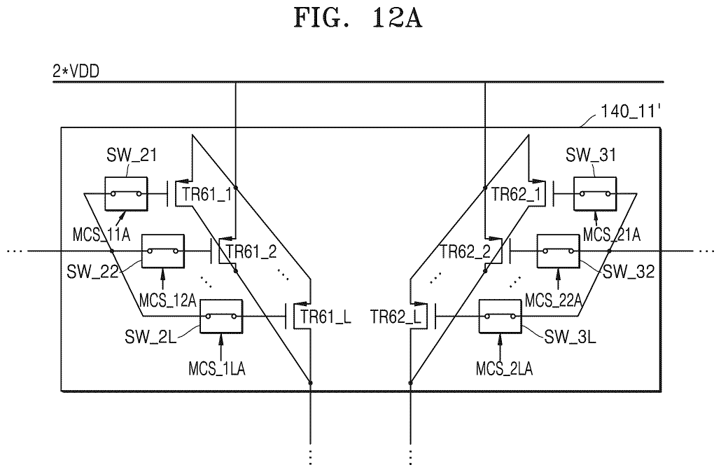

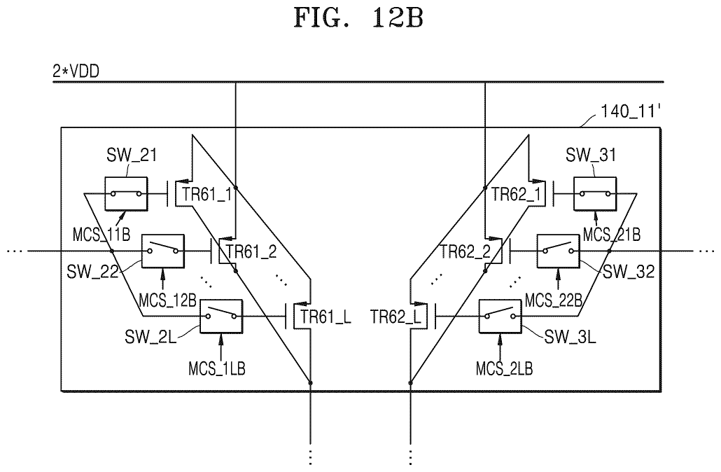

Also, the transistors TR61 TR62 of the first current sensor 140_11 may be variable transistors that may operate based on a mode selected from a general mode and a low power mode. A specific embodiment of transistor TR61 and transistor TR62 of the first current sensor 140_11 will be described below with reference to FIGS. 11 and 12A-12B.

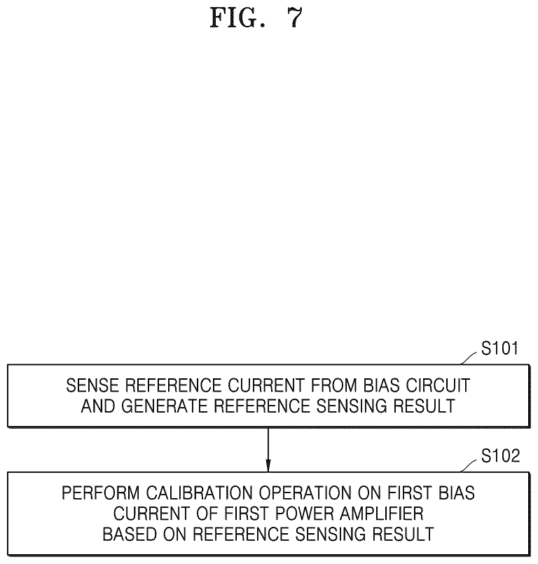

FIG. 7 is a flowchart for describing an operation of calibrating a first bias current of an RF integrated circuit, according to an embodiment. Operations S101 and S102 of FIG. 7 may be included in operation S100 of FIG. 3.

Referring to FIG. 7, in operation S101, an RF integrated circuit may sense a reference current from a bias circuit and may generate a reference sensing result.

In operation S102, the RF integrated circuit may perform a calibration operation on a first bias current of a first power amplifier based on the reference sensing result.

The RF integrated circuit according to an embodiment may calibrate the first bias current so that the first bias current, which is a reference for a calibration operation on second to Kth bias currents of second to Kth power amplifiers, has an optimal value for an operation of the first power amplifier (where K is an integer of two or more, e.g., K=4 in FIG. 5).

FIG. 8 is a block diagram for describing a calibration operation of an RF integrated circuit 100′, according to an embodiment. For convenience of explanation, in the description of FIG. 8, the same description as that made with reference to FIG. 4 will be omitted.

Referring to FIG, 8, the RF integrated circuit 100′ may include the first to fourth power amplifiers 111_21 to 111_24, the first to third current sensors 140_11 to 140_31, the first to third comparators 141_12 to 141_32, a control circuit 116′, a bias circuit 150′, a reference current sensor 111_41, and a reference comparator 141_42.

In an embodiment, the control circuit 116′ may prepare a full-scale calibration operation by first calibrating the first bias current I1_BIAS before sequentially calibrating the second to fourth bias currents I2_BIAS to I4_BIAS.

In an embodiment, the reference current sensor 111_41 and the reference comparator 141_42 may be located between the bias circuit 150′ and the first power amplifier 111_21. The reference current sensor 111_41 may sense a reference current of the bias circuit 150′ and may output a reference sensing result SR_REF, and may sense the first bias current I1_BIAS of the first power amplifier 111_21 and may output the first sensing result SR_1.

In an embodiment, the reference comparator 141_42 may receive the reference sensing result SR_REF through a negative input terminal and may receive the first sensing result SR_1 through a positive input terminal. The reference comparator 141_42 may output a reference comparison result CR_REF based on a difference between the reference sensing result SR_REF and the first sensing result SR_1. In a specific example, the reference comparator 141_42 may output the reference comparison result CR_REF including a plurality of bits indicating how much a first sensing result SR_1 differs from the reference sensing result SR_REF. The control circuit 116 may generate a control signal CS based on the reference comparison result CR_REF and may provide the control signal CS to the bias circuit 150′. The bias circuit 150′ may adjust the first bias BIAS_1 based on the control signal CS.

In an embodiment, the control circuit 116′ may perform the above operation by using the reference current sensor 111_41 and the reference comparator 141_42 at least once to control the first bias current I1_BIAS to approximate a reference current to have a difference less than a threshold value.

The calibrated first bias current I1_BIAS may be sensed by the first current sensor 140_11 and may be output as a first′ sensing result SR_1′, and the first' sensing result SR_1′ may be used to calibrate the second bias current I2_BIAS.

FIG. 9 is a block diagram for describing a calibration operation of the RF integrated circuit 100′, according to an embodiment. For convenience of explanation, in the description of FIG. 9, the same description as that made with reference to FIGS. 5 and 8 will be omitted.

Referring to FIG. 9, the bias circuit 150′ may include the bias generator 151 and transistors TR51′ to TR54. Transistors TR51′ to TR54 may be diode-connected transistors, and transistors TR51′ to TR54 may be both diode-connected and variable transistors.

The first power amplifier 111_21 may receive a first bias through a current mirror including the transistors TR11 and TR51′. The reference current sensor 111_41 may sense a reference current output from the bias generator 151 through a node connected to a drain terminal of transistor TR51′ and may output a reference sensing result SR_REF. Also, the reference current sensor 111_41 may sense the first bias current I1_BIAS of the first power amplifier 111_21 and may output a first sensing result SR_1. The reference comparator 141_42 may compare the reference sensing result SR_REF with the first sensing result SR_1 and may output a reference comparison result CR_REF.

The control circuit 116′ may generate a reference control signal CR_REF for adjusting a width or a length of a channel of transistor TR51′ based on the reference comparison result CR_REF and may provide the reference control signal CR_REF to transistor TR51′. As a result, a ratio between transistor TR51′ and transistor TR11 may change, and thus, the first bias current I1_BIAS may be calibrated.

FIG. 10 is a flowchart for describing a calibration operation according to a mode of an RF integrated circuit, according to an embodiment.

Referring to FIG. 10, in operation S200, an RF integrated circuit may select any one of a general mode and a low power mode. For example, in a test stage for mass production of the RF integrated circuit or mass production of a wireless communication device including the RF integrated circuit, the RF integrated circuit may be set to select the general mode. Also, in a self-calibration stage after shipment of the RF integrated circuit or the wireless communication device including the RF integrated circuit, the RF integrated circuit may be set to select the low power mode. In some embodiments, the RF integrated circuit may adaptively select any one of the general mode and the low power mode based on a power state of the wireless communication device.

In operation S210, the RF integrated circuit may perform a calibration operation on bias currents of a plurality of power amplifiers based on the selected mode. For example, when the general mode is selected, the RF integrated circuit may control current sensors so that sensing performance for the bias currents of the plurality of power amplifiers is maximized, and then may perform a calibration operation. Also, when the low power mode is selected, the RF integrated circuit may control the current sensors so that sensing performance for the bias currents of the plurality of power amplifiers is limited to a preset amount, and then may perform a calibration operation.

FIG. 11 is a block diagram illustrating an RF integrated circuit 100″, according to an embodiment. In FIG. 11, the RF integrated circuit 100″ including a configuration for calibrating the second bias current I2_BIAS of the second power amplifier 111_22 is illustrated, and it will be understood that the embodiment described below may be applied to configurations for calibrating other bias currents. Also, for convenience of explanation, in the description of FIG. 11, the same description as that made with reference to FIG. 6 will be omitted.

Referring to FIG. 11, the RF integrated circuit 100″ may include the first power amplifier 111_21, the second power amplifier 111_22, a first current sensor 140_11′, the first comparator 141_12, and a control circuit 116″.

In an embodiment, the first current sensor 140_11′ may include transistors TR61_1 to TR61_L (where L is an integer of two or more), switch elements SW_21 to SW_2L, transistors TR62_1 to TR62_L, and switch elements SW_31 to SW_3L. Transistors TR61_1 to TR61_L and switch elements SW_21 to SW_2L may be configured to sense a first bias current of the first power amplifier 111_21, and transistors TR62_1 to TR62_L and switches SW_31 to SW_3L may be configured to sense a second bias current of the second power amplifier 111_22.

Source terminals of transistors TR61_1 to TR61_L may be connected to a node to which a first power voltage 2*VDD is applied, drain terminals of transistors TR61_1 to TR61_L may be connected to a negative input terminal of the first comparator 141_12, and gate terminals of transistors TR61_1 to TR61_L may be connected to the switch elements SW_21 to SW_2L in a one-to-one manner.

Source terminals of transistors TR62_1 to TR62_L may be connected to the node to which the first power voltage 2*VDD is applied, drain terminals of transistors TR62_1 to TR62_L may be connected to a positive input terminal of the first comparator 141_12, and gate terminals of transistors TR62_1 to TR62_L may be connected to the switch elements SW_31 to SW_3L in a one-to-one manner.

The control circuit 116″ may generate a first mode control signal MCS_1 and a second mode control signal MCS_2 based on a mode selected from among a general mode and a low power mode. The first mode control signal MCS_1 may include mode control signals MCS_11 to MCS_1L, and the second mode control signal MCS_2 may include mode control signals MCS_21 to MCS_2L. The control signals MCS_11 to MCS_1L and the mode control signals MCS_21 to MCS_2L may also be referred to as mode switching control signals.

Switch elements SW_21 to SW_2L may be turned on/off based on the mode control signals MCS_11 to MCS_1L received from the control circuit 116″. That is, the control circuit 116″ may adjust the number of activated transistors (or the number of transistors connected to transistor TR12) from among the transistors TR61_1 to TR61_L based on the selected mode.

In an embodiment, switch elements SW_31 to SW_3L may be turned on/off based on the mode control signals MCS_21 to MCS_2L received from the control circuit 116″. That is, the control circuit 116″ may adjust the number of activated transistors (or the number of transistors connected to the transistor TR22) from among the transistors TR62_1 to TR62_L based on the selected mode.

The number of activated transistors from among the transistors (e.g., TR61_1 to TR61_L and TR62_1 to TR62_L) of the first current sensor 140_11′ in the low power mode may be less than the number of activated transistors from among the transistors (e.g., TR61_1 to TR61_L and TR62_1 to TR62_L) of the first current sensor 140_11′ in the general mode.

In an embodiment, the number of transistors activated according to a selected mode may be preset, a specific embodiment of which will be described with reference to FIGS. 12A and 12B.

FIGS. 12A and 12B are diagrams for describing an operation of the first current sensor 140_11′ of FIG. 11 according to a selected mode.

Referring to FIG. 12A, the first current sensor 140_11′ may perform a calibration operation based on a general mode. The switch elements SW_21 to SW_2L may be turned on in response to mode control signals MCS_11A to MCS_1LA received from the control circuit 116″ (see FIG. 11). Accordingly, to sense a first bias current of the first power amplifier 111_21 (see FIG. 11), all of transistors TR61_1 to TR61_L may be used. Also, switches SW_31 to SW_3L may be turned on in response to mode control signals MCS_21A to MCS_2LA received from the control circuit 116″ (see FIG. 11). Accordingly, to sense a second bias current of the second power amplifier 111_22 (see FIG. 11), all of transistors TR62_1 to TR62_L may be used.

In some embodiments, a length or a width of a channel of transistors TR61_1 to TR61_L and transistors TR62_1 to TR62_L may be designed so that a first bias current is sensed and a first sensing result corresponding to a certain multiple of the first bias current is output, and a second bias current is sensed and a large second sensing result corresponding to a certain multiple of the second bias current is output. In this case, the general mode may be referred to as an amplification mode.

Referring further to FIG. 12B, the first current sensor 140_11′ may perform a calibration operation based on a low power mode. From among the switch elements SW_21 to SW_2L, only the switch element SW_21 may be turned on in response to mode control signals MCS_11B to MCS_1LB received from the control circuit 116″ (see FIG. 11). Accordingly, to sense a first bias current of the first power amplifier 111_21 (see FIG. 11), only the transistor TR61_1 may be used. Also, from among the switch elements SW_31 to SW_3L, only the switch element SW_31 may be turned on in response to mode control signals MCS_21B to MCS_2LB received from the control circuit 116″ (see FIG. 11). Accordingly, to sense a second bias current of the second power amplifier 111_22 (see 11), only the transistor TR62_1 may be used.

However, this is only an example, the inventive concept is not limited thereto, and in the low power mode, a larger number of transistors may be preset to be used to sense a first bias current of the first power amplifier 111_21 (see FIG. 11) and a second bias current of the second power amplifier 111_22 (see FIG. 11). Furthermore, the low power mode may be further sub-divided and may be adaptively operated according to a power state of a wireless communication device.

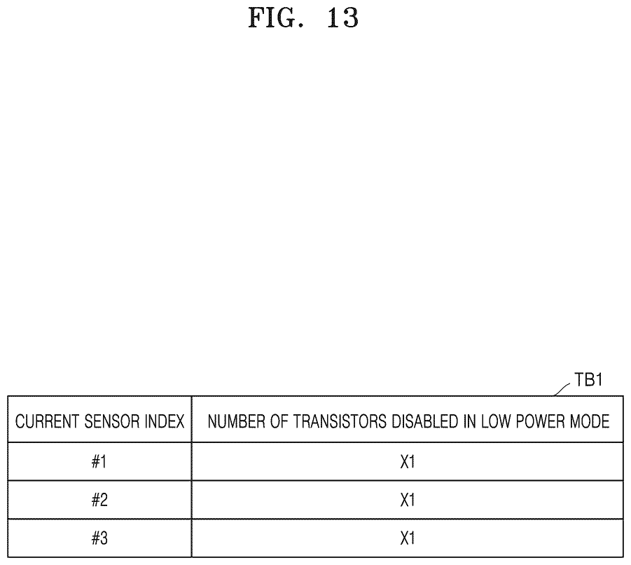

FIG. 13 is a table diagram for describing the number of transistors deactivated in a low power mode for each current sensor, according to an embodiment.

Referring to a first table diagram TB1 of FIG. 13, in first to third current sensors #1 to #3, the same number (‘X1’) of transistors may be deactivated in a low power mode.

For better understanding, referring further to FIG. 4, the first to third current sensors 140_11 to 140_31, #1 to #3 may include the same number of transistors to sense first to fourth bias currents of the first to fourth power amplifiers 111_21 to 111_24, and the number of transistors deactivated in a low power mode may be ‘X1’ and may be the same in all of the first to third current sensors 140_11 to 140_31 (#1 to #3).

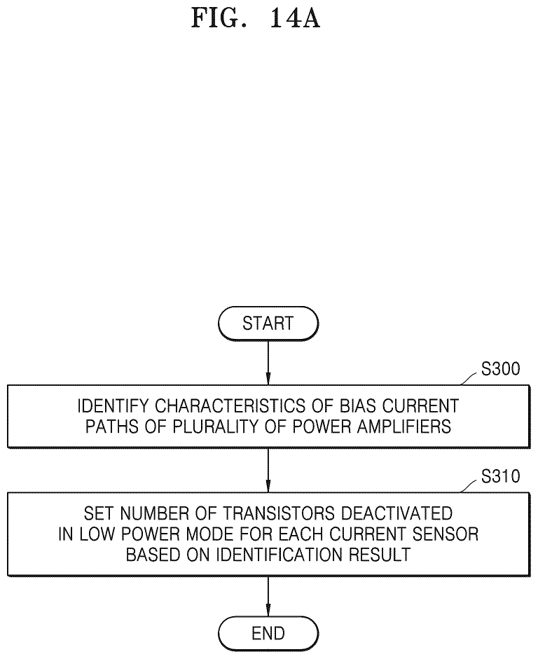

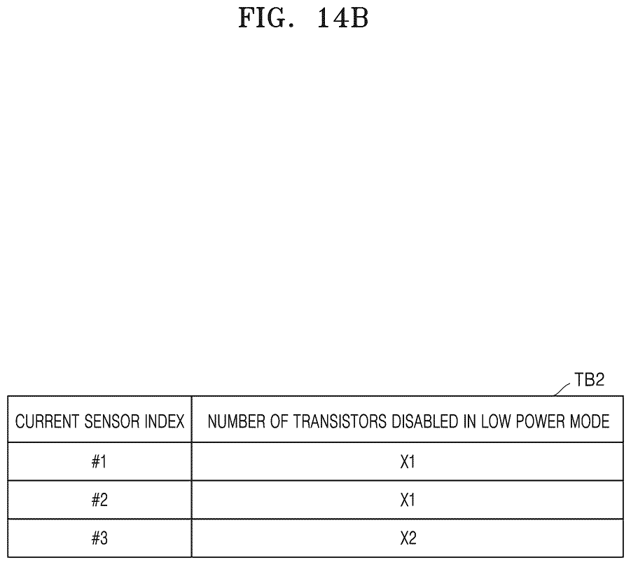

FIGS. 14A and 14B are diagrams for describing a method of determining the number of transistors deactivated in a low power mode for each current sensor, according to an embodiment.

Referring to FIG. 14A, in operation S300, characteristics of bias current paths of a plurality of power amplifiers of an RF integrated circuit may be identified.

In operation S310, the number of transistors deactivated in a low power mode may be set for each current sensor based on an identification result.

In an embodiment, because, when characteristics of a bias current path through which a bias current of an arbitrary power amplifier to be calibrated flows are poor, accurate current sensing is required for effective calibration, the number of transistors deactivated in a low power mode of a current sensor of sensing a bias current of the arbitrary power amplifier may be less than a general number.

Referring to a second table diagram TB2 of FIG. 14B, in first and second current sensors #1 and #2, ‘X1’ transistors may be deactivated in a low power mode, and in a third current sensor #3, ‘X2’ transistors may be deactivated in a low power mode.

For better understanding, referring further to FIG. 4, when characteristics of a bias current path of the fourth power amplifier 111_24 are worse than characteristics of bias current paths of the first to third power amplifiers 111_21 to 111_23, calibration needs to be performed by accurately sensing the fourth bias current I4_BIAS of the fourth power amplifier 111_24. Accordingly, the number (X2) of transistors deactivated in a low power mode of the third current sensor 140_31 (#3) for sensing the fourth bias current I4_BIAS of the fourth power amplifier 111_24 may be less than the number (X1) of transistors deactivated in a low power mode of the first current sensor 140_11 (#1) and the second current sensor 140_21 (#2).

However, this is only an example, and the number of transistors deactivated in a low power mode for each current sensor may be set in various ways.

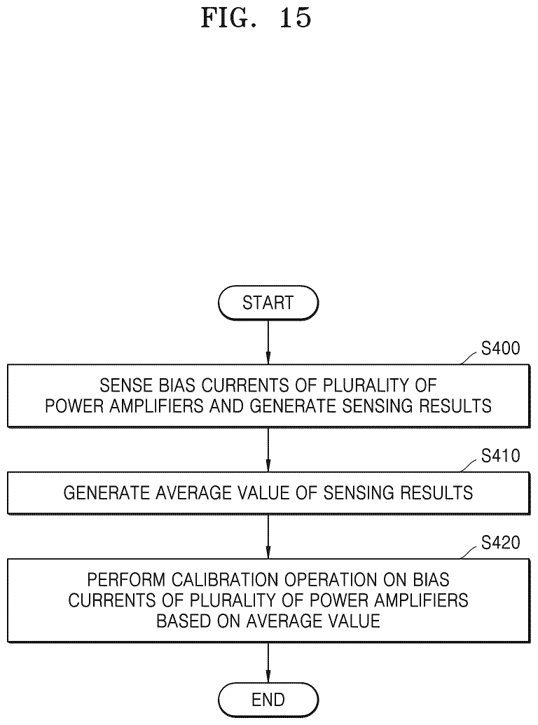

FIG. 15 is a flowchart for describing a calibration operation on bias currents of power amplifiers of an RF integrated circuit, according to an embodiment.

Referring to FIG. 15, in operation S400, an RF integrated circuit may sense bias currents of a plurality of power amplifiers and may generate sensing results.

In operation S410, the RF integrated circuit may generate an average value of the sensing results.

In operation S420, the RF integrated circuit may perform a calibration operation on the bias currents of the plurality of power amplifiers based on the average value.

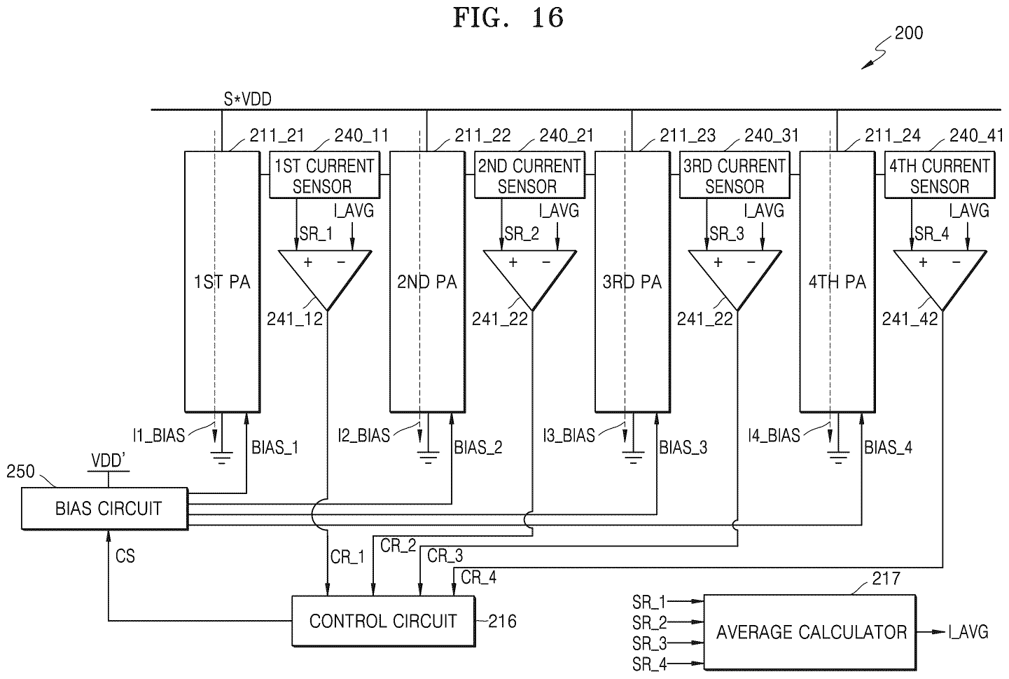

FIG. 16 is a block diagram for describing a calibration operation of an RF integrated circuit 200, according to an embodiment. For convenience of explanation, in the description of FIG. 16, the same description as that with reference to FIG. 4 will be omitted.

Referring to FIG. 16, the RF integrated circuit 200 may include first to fourth power amplifiers 211_21 to 211_24, first to fourth current sensors 240_11 to 240_41, first to fourth comparators 241_12 to 241_42, a control circuit 216, an average calculator 217, and a bias circuit 250. Herein, the bias calibration circuit 12A of FIG. 1A may include the first to fourth current sensors 240_11 to 240_41, the first to fourth comparators 241_12 to 241_42, the control circuit 216, and the average calculator 217.

In an embodiment, the first current sensor 240_11 may sense the first bias current I1_BIAS of the first power amplifier 211_21 and output a first sensing result SR_1, the second current sensor 240_21 may sense the second bias current I2_BIAS of the second power amplifier 211_22 and may output a second sensing result SR_2, the third current sensor 240_31 may sense the third bias current I3_BIAS of the third power amplifier 211_23 and may output a third sensing result SR_3, and the fourth current sensor 240_41 may sense the fourth bias current I4_BIAS of the fourth power amplifier 211_24 and may output a fourth sensing result SR_4.

In an embodiment, the average calculator 217 may output an average value I_AVG of the first to fourth sensing results SR_1 to SR.

In an embodiment, the first comparator 241_12 may receive the first sensing result SR_1 through a positive input terminal and may receive the average value I_AVG through a negative input terminal. The first comparator 241_12 may output a first comparison result CR_1 including a plurality of bits indicating how much the first sensing result SR_1 differs from the average value I_AVG.

In an embodiment, the second comparator 241_22 may receive the second sensing result SR_2 through a positive input terminal and may receive the average value I_AVG through a negative input terminal. The second comparator 241_22 may output a second comparison result CR_2 including a plurality of bits indicating how much the second sensing result SR_2 differs from the average value I_AVG.

In an embodiment, the third comparator 241_32 may receive the third sensing result SR_3 through a positive input terminal and may receive the average value I_AVG through a negative input terminal. The third comparator 241_32 may output a third comparison result CR_3 including a plurality of bits indicating how much the third sensing result SR_3 differs from the average value I_AVG.

In an embodiment, the fourth comparator 241_42 may receive the fourth sensing result SR_4 through a positive input terminal and may receive the average value I_AVG through a negative input terminal. The fourth comparator 241_42 may output a fourth comparison result CR_4 including a plurality of bits indicating how much the fourth sensing result SR_4 differs from the average value I_AVG.

In an embodiment, the control circuit 216 may generate a control signal CS based on the first to fourth comparison results CR_1 to CR_4. The bias circuit 250 may adjust the first to fourth bias currents I1_BIAS to I4_BIAS based on a control signal CS. Accordingly, the first to fourth bias currents I1_BIAS to I4_BIAS may be calibrated to have a difference less than a threshold value.

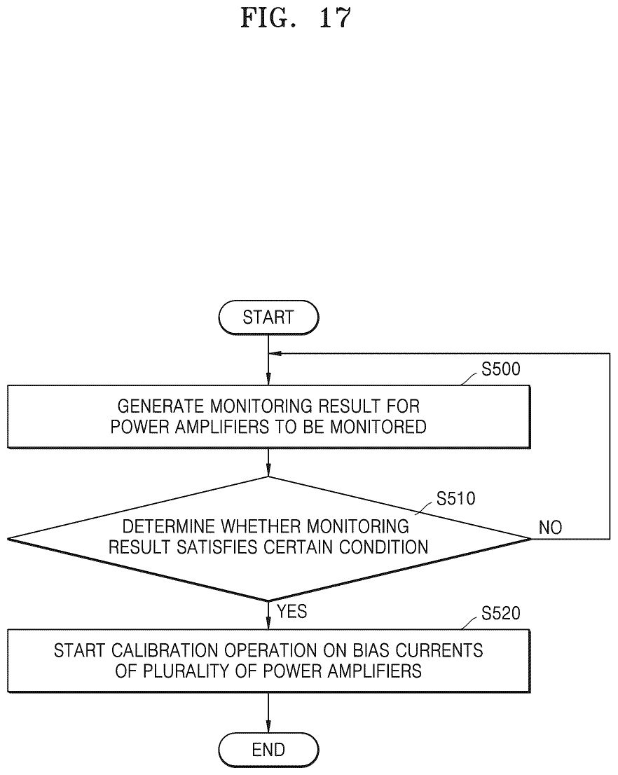

FIG. 17 is a flowchart for describing a method of determining whether to start a calibration operation of an RF integrated circuit, according to an embodiment.

Referring to FIG. 17, in operation S500, an RF integrated circuit may periodically or aperiodically generate a monitoring result for power amplifiers to be monitored.

In operation S510, the RF integrated circuit may determine whether the monitoring result satisfies a certain condition.

When operation S510 is ‘YES’, in operation S520, the RF integrated circuit may start a calibration operation on bias currents of a plurality of power amplifiers.

When operation S510 is ‘NO’, the RF integrated circuit may re-perform operation S500.

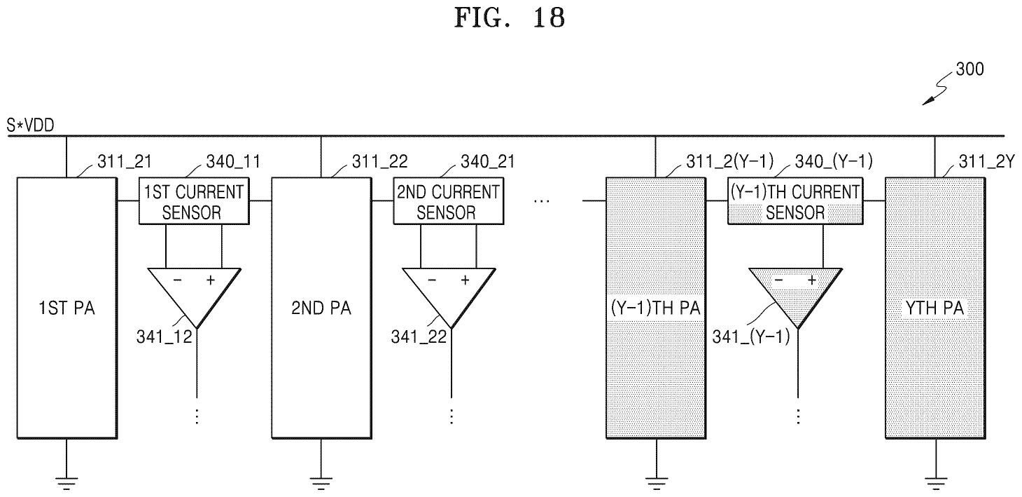

FIG. 18 is a block diagram for describing a calibration operation of an RF integrated circuit 300, according to an embodiment.

Referring to FIG. 18, the RF integrated circuit 300 may include first to Y^{th} (where Y is an integer greater than or equal to 2) power amplifiers 311_21 to 311_2Y, first to Y−1^{th} current sensors 340_11 to 340_(Y−1)1, and first to Y−1^{th} comparators 341_12 to 341_(Y−1)2.

In an embodiment, the Y−1^{th} power amplifier 311_2(Y−1) and the Y^{th} power amplifier 311_2Y may be set as power amplifiers to be monitored, the Y−1^{th} current sensor 340_(Y−1)1 may sense bias currents of the Y−1^{th} power amplifier 311_2(Y−1) and the Y^{th} power amplifier 311_2Y and may output sensing results to the Y−1^{th} comparator 341_(Y−1). The Y−1^{th} comparator 341_(Y−1) may output a comparison result between the sensing results as a monitoring result.

In an embodiment, the RF integrated circuit may determine whether to start a calibration operation on bias currents of the first to Y^{th} power amplifiers 311_21 to 311_2Y based on the monitoring result. When the monitoring result satisfies a certain condition, for example, when the monitoring result exceeds a certain reference value, the RF integrated circuit may determine to start a calibration operation.

FIG. 19 is a diagram illustrating an implementation example of a first power amplifier 400, according to an embodiment.

Referring to FIG. 19, the first power amplifier 400 may include a first matching network 401, a second matching network 402, a first terminal T1, a second terminal T2, a first operational amplifier 403, transistors TR11 and TR71, a first capacitor C1, and a first resistor R1. Herein, the bias calibration circuit 12B of FIG. 1B may include the first operational amplifier 403.

In an embodiment, the first power amplifier 400 may include two amplification stages stacked on each other to form a cascode amplifier configuration, where the amplification stages may include the lower transistor TR11 operating as a first stage (input stage) and ^{t} transistor TR71 operating as a second stage (output stage). The first power amplifier 400 may receive a first power voltage 2*VDD and may perform an amplification operation.

In an embodiment, a first RF signal RF_IN input from the first terminal T1 may be applied to a gate terminal of transistor TR11 through the first matching network 401. Also, a first bias may be applied to the gate terminal of transistor TR11 through a bias circuit 450. A source terminal of transistor TR11 may be grounded, and a drain terminal of the 11^{th} transistor TR11 may be connected to the first bias node N1_BIAS.

In an embodiment, a gate terminal of transistor TR71 may be connected to one end of the first resistor R1 and one end of the first capacitor C1, a drain terminal oft transistor TR71 may be connected to the second matching network 402, and a source terminal of transistor TR71 may be connected to the first bias node N1_BIAS. A bias V1_BIAS may be applied to the gate terminal of transistor TR71 through the other end of the first resistor R1, and the other end of the first capacitor C1 may be grounded.

In an embodiment, the first RF signal RF_IN amplified by the 11^{th} transistor TR11 and transistor TR71 may be output as a first RF output signal RF_OUT through the second matching network 402 and the second terminal T2.

In an embodiment, a first reference voltage V1_REF may be input to a positive input terminal of the first operational amplifier 403, a negative input terminal of the first operational amplifier 403 may be connected to the first bias node N1_BIAS, and a voltage V1 (or a first bias voltage V1) of the first bias node N1_BIAS may be input to the negative input terminal of the first operational amplifier 403. An output terminal of the first operational amplifier 403 may be connected to the gate terminal of transistor TR71.

In an embodiment, the first operational amplifier 403 may form a certain feedback loop and may calibrate the first bias voltage V1 so that the first bias voltage V1 is maintained close to the first reference voltage V1_REF. That is, a level of the first reference voltage V1_REF may correspond to a target level of the first bias voltage V1. In a specific example, the first reference voltage V1_REF may correspond to ‘VDD’ and may be ½ times the first power voltage 2*VDD.

As the first bias voltage V1 is fixed to ‘VDD’ through the first operational amplifier 403 according to an embodiment, the transistor TR11 may perform a stable operation as an amplification stage. Further, source-drain current of each core transistor (transistors TR11 and TR71) may be controlled via the calibration operations so as not to exceed a breakdown voltage.

The bias current calibration operations described above in connection with FIGS. 1A to 18 may be applied in combination with the bias voltage calibration of FIG. 19. In addition, each of the remaining power amplifiers 111_22 to 111_24 of the RF integrated circuit 100, 100′ or 100″ may also include the circuit arrangement of FIG. 19 to calibrate bias voltages therein in an analogous manner. Moreover, each of the remaining power amplifiers 111_22 to 111_24 may also include the circuit arrangements of FIGS. 20-22 described below.

FIG. 20 is a diagram illustrating an implementation example of the bias circuit 450 of FIG. 19. For convenience of explanation, in the description of FIG. 20, the same description as that made with reference to FIG. 19 will be omitted.

Referring further to FIG. 20, the bias circuit 450 may include a bias generator 451, a second operational amplifier 452, and a transistor TR51. Herein, the bias calibration circuit 12B of FIG. 1B may include the first operational amplifier 403 and the second operational amplifier 452.

In an embodiment, the bias generator 451 may generate a reference current based on a supplied second power voltage VDD′, and may be connected to a drain terminal of the transistor TR51 through a second bias node N2_BIAS.

In an embodiment, a first reference voltage V1_REF may be input to a negative input terminal of the second operational amplifier 452, a positive input terminal of the second operational amplifier 452 may be connected to the second bias node N2_BIAS, a voltage V2 (or a “second bias voltage V2”) of the second bias node N2_BIAS may be input to the positive input terminal of the second operational amplifier 452.

In an embodiment, the second operational amplifier 452 may form a certain feedback loop and may calibrate the second bias voltage V2 so that the second bias voltage V2 is maintained close to the first reference voltage V1_REF. That is, a level of the first reference voltage V1_REF may correspond to a target level of the second bias voltage V2. In a specific example, the first reference voltage V1_REF may correspond to ‘VDD’, and may have a lower level than the second power voltage VDD′.

As the second bias voltage V2 is fixed to ‘VDD’ through the second operational amplifier 452 according to an embodiment, the transistor TR51 may perform stable current mirroring. Further, source-drain current of each core transistor (transistors TR11 and TR71) may be controlled via the calibration operations so as not to exceed a breakdown voltage.

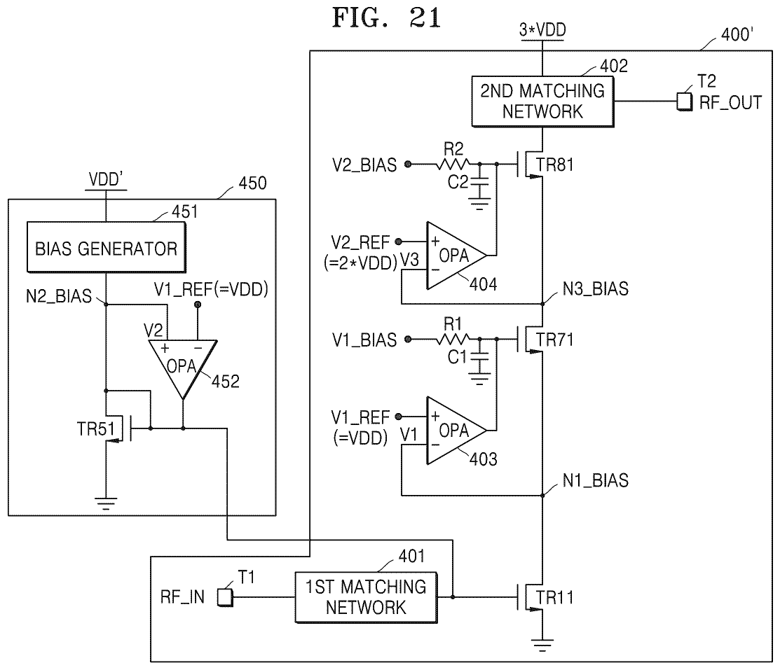

FIG. 21 is a diagram illustrating an implementation example of a first power amplifier 400′, according to an embodiment. For convenience of explanation, in the description of FIG. 21, the same description as that made with reference to FIG. 20 will be omitted.

Referring to FIG. 21, the first power amplifier 400′ may include the first matching network 401, the second matching network 402, the first terminal T1, the second terminal T2, the first operational amplifier 403, a third operational amplifier 404, transistor TR11, transistor TR71, a transistor TR31, the first capacitor C1, the first resistor R1, a second capacitor C2, and a second resistor R2. Herein, the bias calibration circuit 12B of FIG. 1B may include the first to third operational amplifiers 403, 452, and 404.

In an embodiment, the first power amplifier 400′ may include three amplification stages stacked on each other, and the amplification stages may include transistor TR11, transistor TR71, and the transistor TR81. The first power amplifier 400′ may receive a first power voltage 3*VDD and may perform an amplification operation.

In an embodiment, a gate terminal of the transistor TR81 may be connected to one end of the second resistor R2 and one end of the second capacitor C2, a drain terminal of the transistor TR81 may be connected to the second matching network 402, and a source terminal of the transistor TR81 may be connected to a third bias node N3_BIAS. A bias V2_BIAS may be applied to the gate terminal of the transistor TR81 through the other end of the second resistor R2, and the other end of the second capacitor C2 may be grounded. Also, a drain terminal of transistor TR71 may be connected to the third bias node N3_BIAS.

In an embodiment, a first RF signal RF_IN amplified by the 11^{th} transistor TR11, transistor TR71, and transistor TR81 may be output as a first RF output signal RF_OUT through the second matching network 402 and the second terminal T2.

In an embodiment, a second reference voltage V2_REF may be input to a positive input terminal of the third operational amplifier 404, a negative input terminal of the third operational amplifier 404 may be connected to the third bias node N3_BIAS, and a voltage V3 (or a third bias voltage V3) of the third bias node N3_BIAS may be input to THE negative input terminal of the third operational amplifier 404. An output terminal of the third operational amplifier 404 may be connected to the gate terminal of the transistor TR81.

In an embodiment, the third operational amplifier 404 may form a certain feedback loop and may calibrate the third bias voltage V3 so that the third bias voltage V3 is maintained close to the second reference voltage V2_REF. That is, a level of the second reference voltage V2_REF may correspond to a target level of the third bias voltage V3. In a specific example, the second reference voltage V2_REF may correspond to ‘2*VDD’ and may be ⅔ times the first power voltage 3*VDD. Also, a first reference voltage V1_REF may correspond to ‘VDD’ and may be ⅓ times the power voltage 3*VDD.

As the third bias voltage V3 is fixed to ‘2*VDD’ through the third operational amplifier 404 according to an embodiment, transistor TR71 may perform a stable operation as an amplification stage. Further, source-drain current of each core transistor (transistors TR11 and TR71 and TR81) may be controlled via the calibration operations so as not to exceed a breakdown voltage.

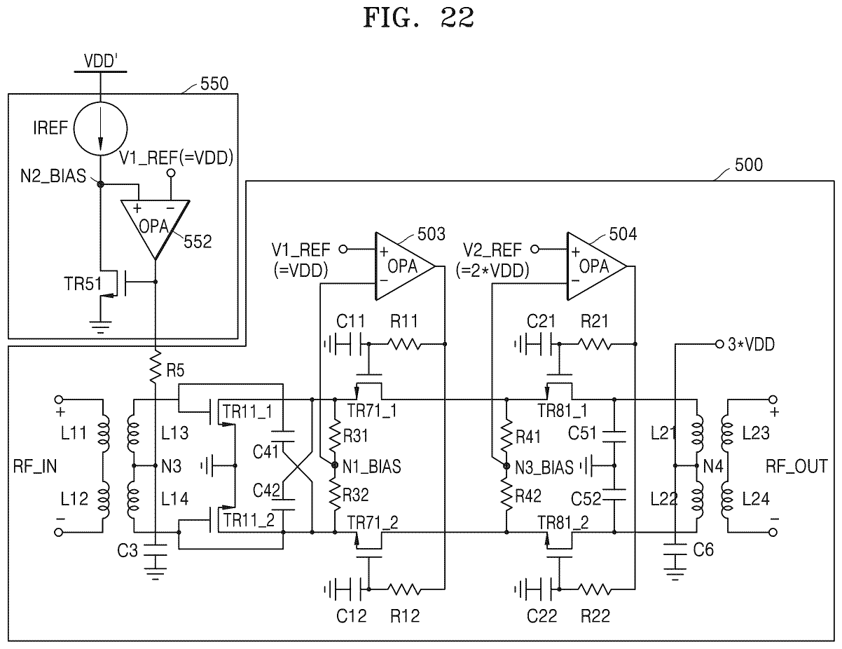

FIG. 22 is a circuit diagram illustrating an implementation example of a first power amplifier 500 and a bias circuit 550, according to an embodiment. The first power amplifier 500 of FIG. 22 may be a differential amplifier.

Referring to FIG. 22, the first power amplifier 500 may include a plurality of inductors (e.g., L11 to L14 and L21 to L24), a plurality of transistors (e.g., TR11_1, TR11_2, TR71_1, TR71_2, TR81_1, and TR81_2), a plurality of capacitors (e.g., C11, C12, C21, C22, C3, C41, C42, C51, C52, and C6), a plurality of resistors (e.g., R11, R12, R21, R22, R31, R32, R41, R42, and R5), a first operational amplifier 503, and a third operational amplifier 504.

Inductors L11 to L14 may constitute a first matching network to which a first RF signal RF_IN is input, a transistor TR11_1, a transistor TR11_2, a capacitor C41, and a capacitor C42 may constitute a first amplification stage, a transistor TR71_1, a transistor TR71_2, a capacitor C11, a capacitor C12, a resistor R11, a resistor R12, a resistor R31, and a resistor R32 may constitute a second amplification stage, a transistor TR81_1, a transistor TR81_2, a capacitor C21, a capacitor C22, a capacitor C51, a capacitor C52, a resistor R21, a resistor R22, a resistor R41, and a resistor R42 may constitute a third amplification stage, and inductors L21 to L24 may constitute a second matching network for outputting a first RF output signal RF_OUT. In an embodiment, the first power amplifier 500 may receive a first power voltage 3*VDD through a fourth node N4.

In an embodiment, a first reference voltage V1_REF that is ‘VDD’ may be input to a positive input terminal of the first operational amplifier 503, a voltage of the first bias node N1_BIAS may be input to a negative input terminal, and an output terminal of the first operational amplifier 503 may be connected to a gate terminal of the 21_1 transistor TR21_1 through the 11^{th} resistor R11 and to a gate terminal of the 21_2 transistor TR21_2 through the 12^{th} resistor R12. Accordingly, the first operational amplifier 503 may calibrate the voltage of the first bias node N1_BIAS and fix the voltage to ‘VDD’.

In an embodiment, a second reference voltage V2_REF that is ‘2*VDD’ may be input to a positive input terminal of the third operational amplifier 504, a voltage of the third bias node N3_BIAS may be input to a negative input terminal, and an output terminal of the third operational amplifier 504 may be connected to a gate terminal of the 31_1 transistor TR31_1 through the 21^{st} resistor R21 and to a gate terminal of the 31_2 transistor TR31_1 through the 22^{nd} resistor R22. Accordingly, the third operational amplifier 504 may calibrate the voltage of the third bias node N3_BIAS and may fix the voltage to ‘2*VDD’.

In an embodiment, the bias circuit 550 may include a reference current source IREF, a second operational amplifier 552, and a 51st transistor TR51.

In an embodiment, the first reference voltage V1_REF that is ‘VDD’ may be input to a negative input terminal of the second operational amplifier 552, a voltage of the second bias node N2_BIAS may be input to a positive input terminal, and an output terminal of the second operational amplifier 552 may be connected to a third node N3 through a fifth resistor R5. Accordingly, the second operational amplifier 552 may calibrate the voltage of the second bias node N2_BIAS and may fix the voltage to ‘VDD’.

However, the embodiment of FIG. 22 is only an example, the inventive concept is not limited thereto, and various implementation examples based on the inventive concept may be applied to power amplifiers and bias circuit of an RF integrated circuit.

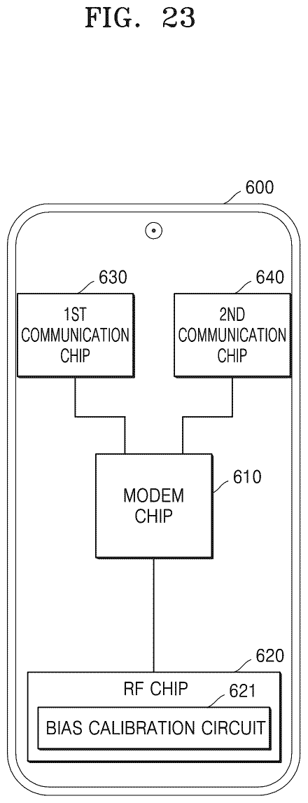

FIG. 23 is a block diagram illustrating a wireless communication device 600, according to an embodiment.

Referring to FIG. 23, the wireless communication device 600 may include a modem chip 610, an RF chip 620, a first communication chip 630, and a second communication chip 640. The modem chip 610 may support various communication networks by using the RF chip 620, the first communication chip 630, and the second communication chip 640.

In an embodiment, the RF chip 620 may include a bias calibration circuit 621. The RF chip 620 may include an RF integrated circuit configured to support communication in a millimeter wave frequency band, and a calibration operation described with reference to FIGS. 1 to 22 may be performed by the bias calibration circuit 621 on bias currents or bias voltages of power amplifiers of the RF chip 620.

In an embodiment, the first communication chip 630 may include an integrated circuit configured to support another network communication with the RF chip 620, and a calibration operation may be performed on bias currents or bias voltages of power amplifiers of the first communication chip 630 based on the inventive concept.

Also, in an embodiment, the second communication chip 640 may include an integrated chip configured to support another network communication with the RF chip 620, and a calibration operation may be performed on bias currents or bias voltages of power amplifiers of the second communication chip 640 based on the inventive concept.

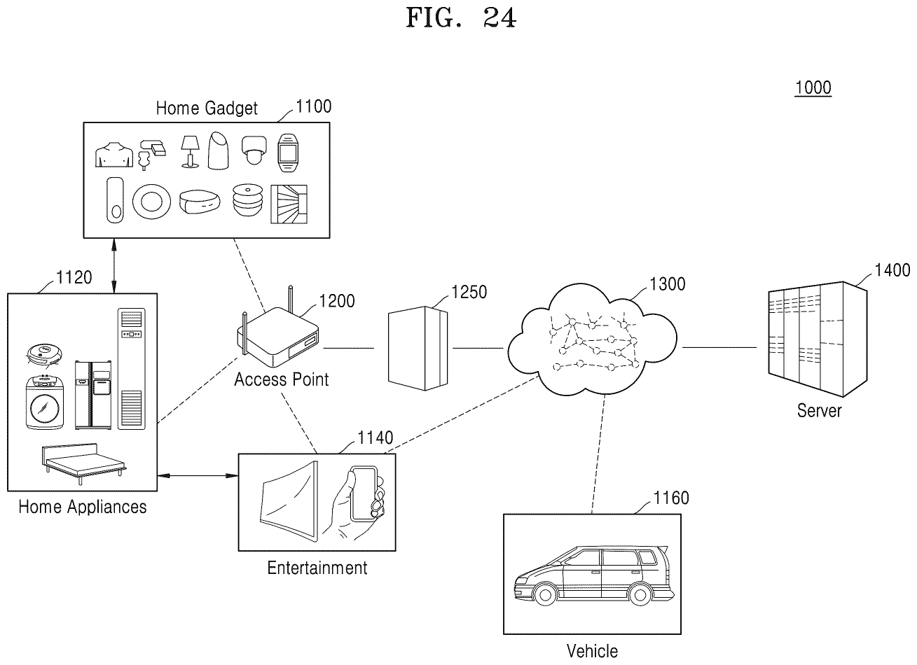

FIG. 24 is a conceptual diagram illustrating an Internet of things (IoT) network system 1000 to which embodiments are applied.

Referring to FIG. 24, an IoT network system 1000 may include a plurality of IoT devices 1100, 1120, 1140, and 1160, an access point 1200, a gateway 1250, a wireless network 1300, and a server 1400. The IoT may refer to a network between objects using wired/wireless communication.

Each of the IoT devices 1100, 1120, 1140, and 1160 may form a group according to characteristics of each IoT device. For example, the IoT devices may be grouped into a home gadget group 1100, a home appliance/furniture group 1120, an entertainment group 1140, or a vehicle group 1160. The plurality of IoT devices 1100, 1120, and 1140 may be connected to a communication network or may be connected to other IoT devices through the access point 1200. The access point 1200 may be provided in one IoT device. The gateway 1250 may change a protocol to connect the access point 1200 to an external wireless network. The IoT devices 1100, 1120, and 1140 may be connected to an external communication network through the gateway 1250. The wireless network 1300 may include the Internet and/or public network. The plurality of IoT devices 1100, 1120, 1140, and 1160 may be connected to the server 1400 that provides a certain service through the wireless network 1300, and a user may use the service through at least one of the plurality of IoT devices 1100, 1120, 1140, and 1160.

According to embodiments, the plurality of IoT devices 1100, 1120, 1140, and 1160 may include a bias calibration circuit, and may perform a calibration operation on bias currents or bias voltages of power amplifiers included therein by using the bias calibration circuit.

Embodiments have been described with reference to the drawings and the specification. While embodiments have been described by using specific terms, the terms have merely been used to explain the inventive concept and should not be construed as limiting the scope of the inventive concept defined by the claims. Hence, it will be understood by one of ordinary skill in the art that various modifications and other equivalent embodiments may be made therefrom. Accordingly, the technical scope of the inventive concept should be defined by the following claims.

While the inventive concept has been particularly shown and described with reference to embodiments thereof, it will be understood that various changes in form and details may be made therein without departing from the spirit and scope of the following claims.

1. A radio frequency (RF) integrated circuit comprising:
a plurality of front-end circuits each connected to an antenna and configured to transmit an RF signal;
a bias circuit configured to provide biases to power amplifiers of the plurality of front-end circuits; and
a bias calibration circuit configured to sense bias currents of the power amplifiers due to the biases and perform a calibration operation on the bias currents based on a result of the bias current sensing.

2. The RF integrated circuit of claim 1, wherein the bias calibration circuit is further configured to, based on an order of proximity to a first power amplifier from among the power amplifiers, sequentially calibrate bias currents of remaining ones of the power amplifiers.

3. The RF integrated circuit of claim 2, wherein the first power amplifier is a power amplifier closest to the bias circuit from among the power amplifiers.

4. The RF integrated circuit of claim 2, wherein the bias calibration circuit is further configured to sense a reference current from the bias circuit and calibrate a first bias current of the first power amplifier based on the reference current.

5. The RF integrated circuit of claim 2, wherein each of the bias currents of the remaining ones of the power amplifiers has a difference less than a threshold value from a first bias current of the first power amplifier through the calibration operation.

6. The RF integrated circuit of claim 1, wherein the power amplifiers comprise a first power amplifier and a second power amplifier adjacent to each other,
wherein the bias calibration circuit is further configured to, based on a difference between first sensing results generated by sensing a first bias current of the first power amplifier and a second bias current of the second power amplifier, calibrate the second bias current.

7. The RF integrated circuit of claim 6, wherein the power amplifiers further comprise a third power amplifier adjacent to the second power amplifier,
wherein the bias calibration circuit is further configured to, based on a difference between second sensing results generated by sensing the calibrated second bias current and a third bias current of the third power amplifier, calibrate the third bias current.

8. (canceled)

9. The RF integrated circuit of claim 1, wherein a first power amplifier from among the power amplifiers comprises:
a first node to which a power voltage is applied; and
an amplification stage configured to amplify a first RF signal,
wherein the bias calibration circuit is further configured to sense a first bias current of the first power amplifier, using a current mirroring circuit arrangement, through a second node between the first node and the amplification stage.

10-11. (canceled)

12. The RF integrated circuit of claim 1, wherein the bias calibration circuit is further configured to perform the calibration operation based on a mode selected from among a general mode and a low power mode.

13-15. (canceled)

16. The RF integrated circuit of claim 1, wherein a first power amplifier from among the power amplifiers comprises amplification stages stacked on each other,
wherein the bias calibration circuit comprises a first operational amplifier configured to calibrate a voltage of a first bias node for connecting the amplification stages to be maintained at a first target level.

17. The RF integrated circuit of claim 16, wherein the bias circuit comprises:
a bias generator configured to generate a reference current; and
a diode-connected transistor configured to output a first bias provided to the first power amplifier from among the biases based on the reference current,
wherein the bias calibration circuit comprises a second operational amplifier configured to calibrate a voltage of a node for connecting the diode-connected transistor to the bias generator to be maintained at a second target level.

18-19. (canceled)

20. A radio frequency (RF) integrated circuit comprising:
a first power amplifier configured to amplify a first RF signal based on a first bias;
a second power amplifier configured to amplify a second RF signal based on a second bias;
a bias circuit configured to provide the first bias to the first power amplifier and provide the second bias to the second power amplifier;
a first current sensor configured to sense a first bias current due to the first bias of the first power amplifier and sense a second bias current due to the second bias of the second power amplifier; and
a first comparator configured to compare a first sensing result corresponding to the first bias current with a second sensing result corresponding to the second bias current and output a corresponding first comparison result,
wherein the bias circuit is further configured to adjust the second bias based on the first comparison result.

21. The RF integrated circuit of claim 20, further comprising:
a third power amplifier configured to amplify a third RF signal based on a third bias;
a second current sensor configured to sense a third bias current due to the third bias provided from the bias circuit of the third power amplifier and a fourth bias current due to the adjusted second bias of the second power amplifier; and
a second comparator configured to compare a third sensing result corresponding to the third bias current with a fourth sensing result corresponding to the fourth bias current and output a second comparison result,
wherein the bias circuit is further configured to adjust the third bias based on the second comparison result.

22. (canceled)

23. The RF integrated circuit of claim 21, wherein the first current sensor comprises first transistors connected in parallel to sense the first bias current and second transistors connected in parallel to sense the second bias current.

24. The RF integrated circuit of claim 23, wherein some of the first transistors and some of the second transistors are deactivated.

25-26. (canceled)

27. The RF integrated circuit of claim 20, further comprising a first operational amplifier configured to maintain a voltage of a first bias node between amplification stages included in the first power amplifier and stacked on each other at a first target level,
wherein the amplification stages comprise:
a first amplification stage configured to receive the first bias and the first RF signal; and
a second amplification stage configured to receive a third bias.

28. The RF integrated circuit of claim 27, wherein
an output terminal of the first operational amplifier is connected to a node of the second amplification stage to which the third bias is applied,
a negative input terminal of the first operational amplifier is connected to the first bias node, and
a positive input terminal of the first operational amplifier is connected to a node to which a reference voltage having the first target level is applied.

29. A radio frequency (RF) integrated circuit comprising:
a first front-end circuit connected to a first antenna and configured to amplify and transmit a first RF signal; and
a bias calibration circuit configured to perform a calibration operation on a first bias voltage of a first power amplifier of the front-end circuit, the first power amplifier including at least first and second stacked amplification stages,
wherein the bias calibration circuit comprises a first operational amplifier connected to the first stacked amplification stage at a first bias node as part of a feedback loop to maintain the first bias node at the first bias voltage in the calibration operation.

30. The RF integrated circuit of claim 29, wherein:
the first and second stacked amplification stages comprise first and second transistors, respectively;
in the first transistor, a first gate terminal is configured to receive the first RF signal and a first bias, a first source terminal is grounded, and a first drain terminal is connected to the first bias node, and
in the second transistor, a second gate terminal is configured to receive a second bias and a second source terminal is connected to the first bias node.

31-34. (canceled)

35. The RF integrated circuit of claim 29, further comprising:
a second front-end circuit connected to a second antenna and configured to amplify and transmit a second RF signal; and
a bias circuit configured to provide a first bias to the first power amplifier and provide a second bias to a second power amplifier included in the second front-end circuit,
wherein the bias calibration circuit is further configured to, based on a difference between sensing results generated by sensing a first bias current due to the first bias of the first power amplifier and a second bias current due to the second bias of the second power amplifier, perform a calibration operation on the second bias current.

36. (canceled)
